(19) United States
(12) Patent Application Publication
(10) Pub. No.: US 2024/0363809 A1
(43) Pub. Date: Oct. 31, 2024

(54) Display Device

(71) Applicant: LG Display Co., Ltd., Seoul (KR)

(72) Inventors: Seung Bum Heo, Paju-si (KR); Han Seok Kim, Paju-si (KR)

(21) Appl. No.: 18/640,430

(22) Filed: Apr. 19, 2024

(30) Foreign Application Priority Data
Apr. 28, 2023 (KR) 10-2023-0056300

(51) Int. Cl. H01L 33/48; H01L 25/16

(52) U.S. Cl. CPC H01L 33/486; H01L 25/167

(57) ABSTRACT

A display device includes a plurality of display modules of which front surfaces have screens on which images are displayed, a plurality of module frames corresponding one-to-one to the display modules, and a tiling frame to which each of the plurality of module frames is fastened to be replaceable. The module frame is coupled to or separated from the tiling frame by a fastening member detachably fastened to the tiling frame and the module frame.

### CROSS-REFERENCE TO RELATED APPLICATION

This application claims priority to and the benefit of Republic of Korea Patent Application No. 10-2023-0056300, filed on Apr. 28, 2023, the disclosure of which is incorporated by reference in its entirety.

### BACKGROUND

### 1. Field of the Invention

The present specification relates to a display device, and more specifically, to a display device in which a display module is replaceable.

### 2. Discussion of Related Art

Organic light emitting diode (OLED) display devices reproduce images by allowing OLEDs disposed in each pixel to emit light according to input image signals. Since an OLED display device has a fast pixel response time, high luminous efficiency and brightness, and a wide viewing angle and may express a black gradation in pure black, the OLED display device has an excellent contrast ratio and an excellent color gamut. The OLED display device does not require a backlight unit.

Recently, display devices using light emitting diodes (LEDs), which are inorganic light emitting elements, as light emitting elements for pixels are attracting attention as next-generation display devices. Since an LED is made of an inorganic material, the LED does not require a separate encapsulation layer for protecting an organic material from moisture, and is more reliable and has a longer lifetime than the OLED. In addition, the LED has a fast-lighting speed, excellent luminous efficiency, and impact resistance.

### SUMMARY

In a tiling display device implementing a large screen by connecting a plurality of display modules on the same plane, a technology for applying pixels of display modules as light emitting elements is being developed. Each of the display modules includes a display panel, on which a plurality of pixels are disposed, and a driving circuit thereof. However, the display module is not easily replaced due to a fastening structure of the tiling display device.

The present disclosure is directed to providing a display device in which a display module is replaceable in a tiling display device.

The objects of the present disclosure are not limited to the above-described objects, and other objects that are not mentioned will be able to be clearly understood by those skilled in the art from the following description.

A display device according to one embodiment of the present disclosure includes a plurality of display modules of which front surfaces have screens on which images are displayed, a plurality of module frames corresponding one-to-one to the display modules, and a tiling frame to which each of the plurality of module frames is fastened to be replaceable.

A display device according to another embodiment of the present disclosure includes a first display module and a second display module, a first module frame to which the first display module is attached, a second module frame to which the second display module is attached, and a tiling frame to which the first and second display modules are fastened to be replaceable.

A display device according to another embodiment of the present disclosure includes N display modules, wherein N is a natural number of 2 or more, and a frame to which each of the display modules is fastened to be replaceable, wherein the frame includes a first frame configured to support one surface of each of the display modules so that the N display modules are disposed on the same plane; and a plurality of second frames configured to support one surface of each of M display modules, wherein M is a natural number greater than zero and less than N, each of the second frames is interposed between one of the display modules corresponding thereto and the first frame, and each of the second frames is fastened to the first frame to be replaceable.

### BRIEF DESCRIPTION OF THE DRAWINGS

FIG. 1 is a block diagram showing a configuration of a display device according to one embodiment of the present disclosure.

FIG. 2 is a partial cross-sectional view showing pad parts and a side line disposed on an outermost portion of a display panel according to one embodiment of the present disclosure.

FIG. 3 is a perspective view showing the display device according to one embodiment of the present disclosure.

FIG. 4 is a block diagram showing control boards connected to a plurality of printed circuit boards and a system board connected to the control boards in the display device according to one embodiment of the present disclosure.

FIG. 5 is a plan view showing a planar structure of the display panel in the display device according to one embodiment of the present disclosure.

FIG. 6 is a cross-sectional view specifically showing a cross-sectional structure of the display panel in the display device according to one embodiment of the present disclosure.

FIG. 7 is a plan view showing a tiling frame to which a plurality of display modules are coupled according to one embodiment of the present disclosure.

FIG. 8 is a perspective view showing the tiling frame to which the plurality of display modules are coupled according to one embodiment of the present disclosure.

FIG. 9 is a cross-sectional view of the display device along line A-A′ in FIG. 8, which is a combined cross-sectional view showing a portion in which a module frame coupled to each of the display modules is coupled to the tiling frame by a screw in the display device according to one embodiment of the present specification.

FIG. 10 is an exploded perspective view showing that a plurality of display modules are disassembled from the tiling frame, and a display module to be replaced among the plurality of display modules is disassembled according to one embodiment of the present disclosure, which is an exploded perspective view.

FIG. 11 is a plan view showing the module frame to which the display module is coupled in the display device according to one embodiment of the present disclosure.

FIG. 12 is an exploded perspective view showing the display module and the module frame in the display device according to one embodiment of the present disclosure.

FIG. 13 is a perspective view showing a state in which the plurality of display modules are fixed to a frame according to one embodiment of the present disclosure.

FIG. 14 is an enlarged view of portion Q1 in FIG. 13 according to one embodiment of the present disclosure.

FIG. 15 is a cross-sectional view of the display module along line F-F′ in FIG. 14 according to one embodiment of the present disclosure.

FIG. 16 is a view showing shapes of electrode pads disposed on the display panels of neighboring display modules according to one embodiment of the present disclosure.

FIG. 17 is a view showing a first modified example of the electrode pads of FIG. 16 according to one embodiment of the present disclosure.

FIG. 18 is a view showing a state in which two display modules are disposed according to FIG. 17 according to one embodiment of the present disclosure.

FIG. 19 is a view showing a second modified example of the electrode pads of FIG. 16 according to one embodiment of the present disclosure.

FIG. 20 is a view showing a cross-sectional structure of two display modules according to FIG. 19 according to one embodiment of the present disclosure.

FIG. 21 is a plan view showing a state in which a plurality of display modules are coupled to a frame according to one embodiment of the present disclosure.

FIG. 22 is a cross-sectional view of the display modules along line H-H′ in FIG. 21 according to one embodiment of the present disclosure.

FIG. 23 is a combined cross-sectional view showing a module frame structure in which the tiling frame and the display modules are coupled by a screw according to one embodiment of the present disclosure.

FIG. 24 is an exploded cross-sectional view showing a state in which a module frame coupled to a rear surface of the display module to be replaced is separated from the tiling frame in the display device according to one embodiment of the present disclosure.

FIG. 25 is an enlarged view showing dotted line portion “I” in FIG. 23 in the display device, which is a cross-sectional view before a module frame to which a replaced display module is coupled and the tiling frame are coupled and a cross-sectional view showing a screw onto which a silicone ring for adjusting a step difference between the tiling frame and the module frame is fitted according to one embodiment of the present disclosure.

FIG. 26 is an enlarged view showing dotted line portion “I” in FIG. 23 in the display device, which is a combined cross-sectional view showing a coupling state of the display device in which the tiling frame and the replaced display module are coupled is coupled by the screw and a step difference between the tiling frame and the module frame is adjusted according to the compression amount of the silicon ring according to one embodiment of the present disclosure.

### DETAILED DESCRIPTION

Advantages and features of the present disclosure and methods for achieving them will become clear with reference to embodiments described below in detail in conjunction with the accompanying drawings. The present invention is not limited to the embodiments disclosed below but can be implemented in various different forms, these embodiments are merely provided to make the disclosure of the present invention complete and fully inform those skilled in the art to which the present invention pertains of the scope of the present invention, and the present invention is only defined by the scope of the appended claims.

In describing the present invention, when it is determined that the detailed description of a related known technology may unnecessarily obscure the gist of the present invention, detailed description thereof will be omitted.

When the terms “comprise,” “include,” “have,” and “comprising” described in the present specification are used, other parts may be added unless “only” is used. When a component is expressed in the singular, it can be construed as a plurality of components unless specifically stated otherwise.

When the position relationship and interconnection relationship between two components, such as “on,” “above,” “under,” “next to,” “connected or coupled,” “crossing or intersecting,” or the like described, one or more other components may be interposed between the components unless the term “immediately” or “directly” is described.

When the temporal relationship is described using the term “after,” “subsequently,” “then,” “before,” or the like, it may include a non-consecutive case unless the term “immediately” or “directly” is used.

Although the term “first,” “second,” or the like may be used to distinguish components, functions or structures of the components are not limited by the ordinal number or component name added to the front of the component.

The following embodiments may be partially or fully coupled or combined, and various technological interworking and driving are possible. The embodiments may be implemented independently of each other and implemented together in the associated relationship.

Terms (including technical and scientific terms) used in embodiments of the present specification may be construed as meaning that may be generally understood by those skilled in the art to which the present specification pertains unless explicitly specifically defined and described, and the meanings of the commonly used terms, such as terms defined in a dictionary, may be construed in consideration of contextual meanings of related technologies.

Hereinafter, exemplary embodiments according to the present invention will be described in detail with reference to the accompanying drawings.

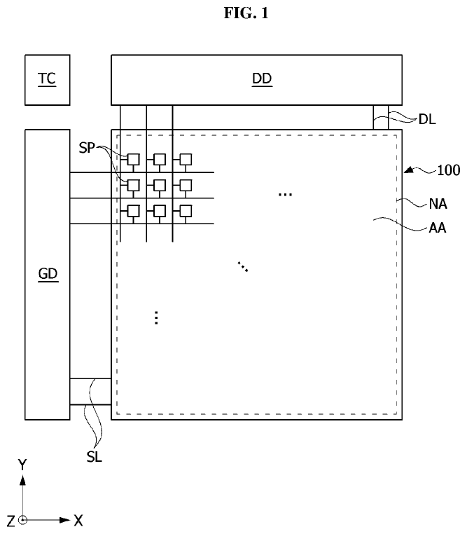

FIG. 1 is a block diagram schematically showing a configuration of a display device according to one embodiment of the present disclosure.

Referring to FIG. 1, the display device includes a display panel 100 in which a plurality of pixels are disposed in a display area AA, and a driving circuit for driving the pixels.

The display panel 100 may be a panel with a rectangular structure having a length in a X-axis direction, a width in a Y-axis direction, and a thickness in a Z-axis direction. The pixels include a plurality of sub-pixels SP for emitting different colors. The driving circuit includes a data driver DD, a gate driver GD, and a timing controller TC for controlling the gate driver GD and the data driver DD. In the display panel 100, the display area AA on which an input image is displayed may be a screen visible at a front surface of the display panel 100. Here, a width and length of the display panel 100 may be set to various design values depending on application fields of the display device. In addition, the X-axis direction may be a longitudinal direction or lateral direction, the Y-axis direction may be a width direction or breadth direction, and the Z-axis direction may be a vertical direction or thickness direction. In addition, the X-axis direction, the Y-axis direction, and the Z-axis direction may be perpendicular to each other, but may also be different directions which are not perpendicular to each other. Therefore, each of the X-axis direction, the Y-axis direction, and the Z-axis direction may be described as any one of a first direction, second direction, or third direction. In addition, a surface extending in the X-axis direction and Y-axis direction may indicate a horizontal surface.

An input image is displayed by the sub-pixels SP disposed on the display area AA of the display panel 100. Each of the sub-pixels SP includes a light emitting element and a pixel circuit for driving the light emitting element. The light emitting element may be a light emitting diode (LED) or micro-LED.

A plurality of scan lines SL and a plurality of data lines DL are disposed to intersect each other on the display panel 100. Each of the sub-pixels SP is connected to the scan line SL and the data line DL. Power lines omitted from FIG. 1 may be connected to each of the sub-pixels SP. A non-display area NA may be disposed outside the display area AA in the display panel 100.

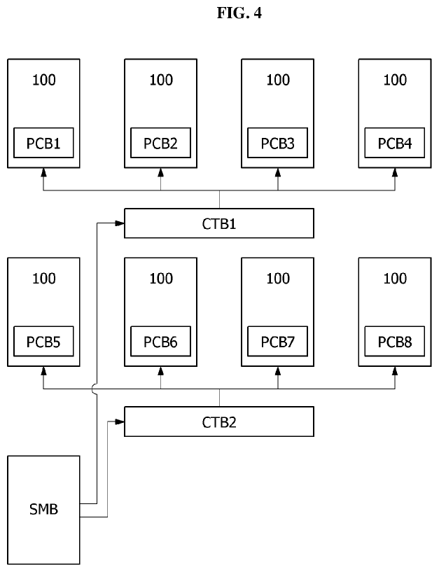

The gate driver GD supplies a scan signal to the scan lines SL in response to a gate control signal provided from the timing controller TC. The gate driver GD may be at least disposed on the non-display area NA of the display panel 100 as shown in FIG. 1 or disposed on the display area AA as shown in FIG. 4, which will be described below.

The data driver DD converts image data received from the timing controller TC into reference compensation voltages in response to data control signals provided from the timing controller TC and outputs data voltages. The data voltages output from the data driver DD are supplied to the data lines DL.

The timing controller TC aligns the image data input from the outside and supplies the sorted image data to the data driver DD. The timing controller TC may generate a gate control signal and a data control signal based on timing signals, which are synchronized with the input image signal, such as a dot clock signal, a data enable signal, and horizontal/vertical synchronization signals. The timing controller TC supplies the gate control signal to the gate driver GD and supplies the data control signal to the data driver DD to control operation timings of the gate driver GD and the data driver DD.

Link lines and pad electrodes for transmitting the signals to the sub-pixels SP of the display area AA may be disposed on the non-display area NA. In addition, at least one of a gate driver integrated circuit (IC) in which circuits of the gate driver GD are integrated and a data driver IC in which circuits of the data driver DD are integrated may be disposed in the non-display area NA. The non-display area NA may be positioned on a rear surface of the display panel 100, that is, a rear surface in which the sub-pixel SP is not present or minimized to a degree at which the non-display area NA is invisible when the image is displayed on the display panel 100.

The drivers such as the gate driver GD, the data driver DD, and the timing controller TC may be connected to the display panel 100 in various ways. For example, the gate driver GD may be disposed on the non-display area NA in a gate in panel (GIP) method, and disposed between the sub-pixels SP in the display area AA in a gate in active area (GIA) method. For example, the data driver DD and the timing controller TC may be formed on a separate flexible film and printed circuit board (hereinafter referred to as “PCB”), and the data driver DD and the timing controller TC may be electrically connected to the display panel 100 by bonding the flexible film and the PCB to the pad electrodes formed in the non-display area NA of the display panel 100.

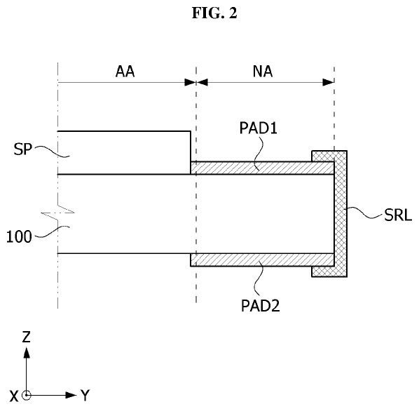

Side lines for connecting the signal lines on the front surface of the display panel 100 to the pad electrodes on the rear surface of the display panel 100 may be formed on a side surface of an outermost portion of the display panel 100. A method of electrically connecting the front and rear surfaces of the display panel 100 through the side lines can maximally reduce the non-display area NA when viewing the display panel 100 from the front. In FIG. 2, “SRL” indicates the side line. When the gate driver GD, the data driver DD, and the timing controller TC are connected to the display panel 100 in the above manner, a substantially bezel-less screen can be implemented.

FIG. 2 is a partial cross-sectional view showing pad parts and a side line disposed on an outermost portion of a display panel according to one embodiment of the present disclosure.

Referring to FIG. 2, a plurality of pad electrodes for transmitting various signals to the sub-pixels SP are disposed on the non-display area NA of the display panel 100. For example, a first pad electrode PAD1 for transmitting signals to the sub-pixels SP may be disposed on the non-display area NA disposed on the front surface of the display panel 100. A second pad electrode PAD2 electrically connected to circuit components such as the flexible film and the PCB is disposed on the non-display area NA disposed on the rear surface of the display panel 100. A size of the non-display area NA disposed on an outermost portion of the front surface of the display panel 100 on which the images are displayed can be minimized or at least reduced by arranging only a pad area in which the first pad electrode PAD1 is disposed.

Various signal lines connected to the sub-pixels SP, for example, the scan line SL, the data line DL, and the like may extend to the non-display area NA and may be electrically connected to the first pad electrode PAD1.

The display panel 100 may include the side line SRL disposed on the side surface of the outermost portion of the display panel 100. The side line SRL may connect the first pad electrode PAD1 disposed on the outermost portion of the front surface of the display panel 100 to the second pad electrode PAD2 disposed on an outermost portion of the rear surface of the display panel 100 across the side surface of the display panel 100. Signals output from the circuit components disposed on the rear surface of the display panel 100 may be transmitted to the sub-pixel SP in the display area AA through the second pad electrode PAD2, the side line SRL, and the first pad electrode PAD1. Therefore, by forming a signal transmission path which is formed through the front, side, and rear surfaces of the outermost portion of the display panel 100, it is possible to minimize an area of the non-display area NA on the front surface of the display panel 100.

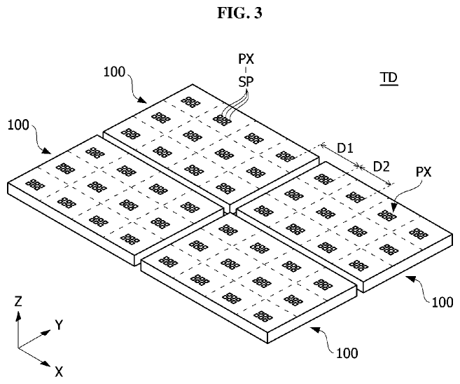

FIG. 3 is a perspective view showing the display device according to one embodiment of the present disclosure.

As shown in FIG. 3, a plurality of display modules may be coupled in a plan view and implemented as a large-screen tiling display device. Each of the display modules can be implemented as a single display device and implemented as the large-screen tiling display device through a combination of the plurality of display modules. Each of the display modules may include one display panel 100, the driving circuit of the display panel 100, and the circuit components and module cover members coupled to the rear surface of the display panel 100.

Referring to FIG. 3, a large-screen tiling display device TD includes a plurality of display modules disposed on an XY plane. Each of the display modules includes the display panel 100 for reproducing the input images. When the non-display area NA on the outermost portion of the front surface of each of the display panels 100 is minimized or at least reduced, the tiling display device TD may reproduce a large-screen image without visible seams between adjacent display panels 100.

In the tiling display device TD, outermost pixels PX of two neighboring display panels 100 are disposed to have a predetermined distance D1. In addition, neighboring pixels PX in the display area AA of the display panel 100 are also disposed to have a distance D2 which is substantially the same as the distance D1. As a result, the distance D1 between the pixels PX is the same throughout a large-screen display area of the tiling display device TD, and a seam area is invisible.

In the tiling display device TD, the plurality of display modules may share one timing controller TC. A host system may be connected to a plurality of timing controllers TC to transmit image signals to be reproduced on all display panels 100 which implement the large screen of the tiling display device TD to the timing controllers TC and may synchronize the timing controllers TC.

FIG. 4 is a block diagram showing control boards connected to a plurality of printed circuit boards and a system board connected to the control boards in the display device according to one embodiment of the present disclosure.

Referring to FIG. 4, each of the display modules may include one display panel 100 and one PCB. A system board SMB is connected to M control boards CTB1 and CTB2 (M is an integer of 2 or more). Each of the control boards CTB1 and CTB2 is connected to N PCBs (N is an integer greater than M).

The first control board CTB1 may be connected to PCBs PCB1 to PCB4 of the first to fourth display modules through a flexible film or cable. The second control board CTB2 may be connected to PCBs PCB5 to PCB8 of the fifth to eighth display modules through a flexible film or cable. The system board SMB may be connected to the first and second control boards CTB1 and CTB2 through a flexible film or cable.

The system board SMB may be a main board of the host system. The system board SMB includes a user interface port for receiving user inputs, an external interface port connected to external devices, a communication module for supporting various communication protocols, a processor for processing multi-media signals, a central processing unit (CPU), a main power supply unit, and the like. The system board SMB transmits the input image signal and the timing signal to the control boards CTB1 and CTB2. The timing controllers TC mounted on the control boards CTB1 and CTB2 transmit the received image signal to the data driver DD and controls the data driver DD and the gate driver GD based on the timing signal. The driving circuits DD and GD of the N display modules write image data to the corresponding display panel 100 under the control of one timing controller TC.

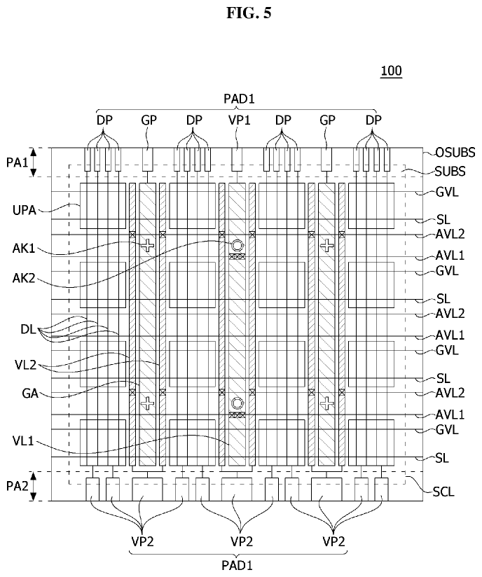

FIG. 5 is a plan view showing a planar structure of the display panel according to the one embodiment of the present disclosure.

Referring to FIG. 5, the display panel 100 includes a substrate SUBS on which a pixel array and the circuits of the gate driver GD are disposed.

The substrate SUBS may be an insulating substrate for supporting components disposed on an upper portion of the display device. As shown in FIG. 6, the substrate SUBS may have a structure in which first and second substrates SUBS1 and SUBS2 are stacked. Each of the first and second substrates SUBS1 and SUBS2 may be manufactured of a glass, a polymer resin, or a plastic substrate. Each of the first and second substrates SUBS1 and SUBS2 may be manufactured as a flexible substrate, but is not limited thereto.

On one surface (or a front surface) of the substrate SUBS, the display area AA may include a plurality of pixel areas UPA, a plurality of gate driving areas GA, and a plurality of pad areas PA1 and PA2. One or more pixels PX may be disposed on each of the pixel areas UPA. The pixel areas UPA may be disposed along a plurality of row lines and a plurality of column lines. Each of the pixels PX includes a plurality of sub-pixels SP for emitting different colors. Each of the sub-pixels SP may include a light emitting element and a pixel circuit and emit light independently. The sub-pixels SP may include a red sub-pixel, a blue sub-pixel, and a green sub-pixel, but is not limited thereto.

The plurality of gate driving areas GA include the circuits of the gate driver GD. The gate driving area GA may be formed in row and/or column directions between the plurality of pixel areas UPA. The gate driver GD formed in the gate driving area GA may provide a scan signal to the plurality of scan lines SL.

The first pad area PA1 includes a plurality of first pad electrodes PAD1 disposed on a front surface of an outermost portion of one side (or an upper side) of the display panel 100. The first pad electrodes PAD1 may transmit various signals to various lines extending in the column direction in the display area AA. The first pad electrodes PAD1 includes data pads DP connected to the data lines DL and for transmitting the data voltage from the data driver DD to the data lines DL, and gate pads GP connected to the gate driver GD and for transmitting a clock signal, a start signal, a gate low voltage, a gate high voltage, and the like for driving the gate driver GD to the gate driver GD. The clock signal, start signal, gate low voltage, gate high voltage, and the like for driving the gate driver GD may be generated from the timing controller TC and applied to the gate pads GP via a level shifter and the PCB. The first pad electrodes PAD1 may include a plurality of power supply lines to which a DC voltage (or a constant voltage) is applied.

The second pad area PA2 includes a plurality of first pad electrodes PAD1 disposed on a front surface of an outermost portion of the other side (or a lower side) of the display panel 100. The second pad area PA2 may include a plurality of low-potential power pads VP2.

The DC voltage applied to the power lines may be output from the power circuit omitted in the drawing and applied to the pads VP1 and VP2 connected to the power lines through the PCB. The power circuit may be a DC-DC converter disposed on the PCB or control boards CTB1 and CTB2 disposed on the rear surface of the display panel 100 to convert a DC input voltage from a main power supply unit into a direct voltage suitable for driving the display panel 100.

The power pads VP1 and VP2 connected to the power lines may include a plurality of high-potential power pad VP1 disposed on the first pad area PA1 to transmit a high-potential power voltage to a high-potential power line VL1, and a plurality of low-potential power pads VP2 disposed on the second pad area PA2 to transmit a low-potential power voltage to a low-potential power line VL2.

The data pads DP connected one-to-one to the data lines DL may have a relatively smaller width, and the power pads VP1 and VP2 and the gate pads GP may have relatively larger widths. The low-potential power pads VP2 may have larger widths than the high-potential power pads VP2. The widths of the pads DP, GP, VP1, and VP2 are not limited to those of FIG. 5.

In order to minimize or reduce the outermost non-display area NA of the display panel 100, after the pixel array, lines, and pads are formed on a front surface of the substrate SUBS of the display panel 100, the substrate SUBS is cut along a scribing line SCL. Therefore, the substrate SUBS may be provided after removing a portion OSUBS outside the scribing. After the scribing process, rough edges on a side surface of an outermost portion of the substrate SUBS may be ground or laser-trimmed. As described above, short pad electrodes PAD1 and PAD2 remain on the front surface of the outermost portion of the substrate SUBS with the reduced size.

The data lines DL may extend in the column direction (Y direction) on the first substrate SUBS and overlap the pixel area UPA. The data lines DL supply data voltages to the pixel circuit of each sub-pixel SP. The scan lines SL may extend in the row direction (X direction) on the substrate SUBS of the display panel 100 and overlap the pixel area UPA and the gate driving area GA. The scan lines SL may supply the scan signal from the gate driver GD to the pixel circuit of each of the sub-pixels SP across the pixel area UPA and the gate driving area GA.

The high-potential power lines VL1 extend in the column direction (Y direction), and at least one of the high-potential power lines VL1 is connected to an auxiliary high-potential power line AVL1 extending in the row direction (X direction) in a mesh structure. The auxiliary high-potential power lines AVL1 are connected to the sub-pixels SP disposed in the row direction (X direction). Therefore, the high-potential power voltage applied to the high-potential power lines VL1 may be transmitted to the sub-pixels SP through the auxiliary high-potential power lines AVL1.

The low-potential power lines VL2 extend in the column direction (Y direction), and at least one of the low-potential power lines VL2 is connected to an auxiliary low-potential power line AVL2 extending in the row direction (X direction) in a mesh structure. The auxiliary low-potential power lines AVL2 are connected to the sub-pixels SP disposed in the row direction (X direction). Therefore, the sub-pixels SP are connected to the auxiliary high-potential power lines AVL1 to which the low-potential power voltages are applied.

Due to the mesh structure of the power lines, resistances of the power lines can be reduced, thereby minimizing or at least reducing a voltage drop of the high-potential power voltage and a deviation of the power voltage in the display area AA.

A plurality of gate driving lines GVL extending in the row direction are disposed on the first substrate SUBS1 of the display panel 100. The plurality of gate driving lines GVL transmit signals necessary for driving the gate driver GD disposed on the gate driving area GA, such as a clock signal, a start signal, a gate high voltage, and a gate low voltage.

The substrate SUBS of the display panel 100 may include one or more alignment keys AK1 and AK2 disposed between the pixel areas UPA. The alignment keys AK1 and AK2 may be used for alignment in the manufacturing process of the display panel 100. The first alignment key AK1 may be disposed on the gate driving area GA. The first alignment key AK1 may be used to check an alignment position of each of the light emitting elements. The first alignment key AK1 may be formed in a cross pattern, but is not limited thereto. The second alignment key AK2 may overlap the high-potential power line VL1. The high-potential power line VL1 includes a hole formed at a position overlapping the second alignment key AK2 to distinguish the second alignment key AK2 from the high-potential power line VL1. The second alignment key AK2 may be used to align the display panel 100 with a donor substrate. The donor substrate is an intermediate medium for mounting the light emitting element on the substrate SUBS of the display panel 100. A plurality of light emitting elements manufactured on a semiconductor wafer may be transported after being attached to the donor substrate, and the light emitting elements attached on the donor substrate may be transferred onto the substrate SUBS. The second alignment key AK2 may be formed in a circular or ring pattern, but is not limited thereto.

FIG. 6 is a cross-sectional view showing a cross-sectional structure of the display panel according to the one embodiment of the present disclosure.

Referring to FIG. 6, a pixel circuit for driving a light emitting element ED is disposed in each of the plurality of sub-pixels SP on the first substrate SUBS1. The pixel circuit may include a plurality of thin film transistors and one or more capacitors. Although a driving transistor DT, a first capacitor C1, and a second capacitor C2 used for the pixel circuit are shown for convenience of description, the display panel 100 may further include other circuit devices.

A pattern of a first metal layer may be disposed on the first substrate SUBS1. The pattern of the first metal layer may include a light blocking layer BSM. The light blocking layer BSM can minimize or at least reduce a leakage current by blocking light incident on an active layer ACT of the driving transistor DT. The light blocking layer BSM may be made of an opaque conductive material, for example, a metal such as copper (Cu), aluminum (Al), molybdenum (Mo), nickel (Ni), titanium (Ti), or chromium (Cr), made of an alloy of these metals, or formed as a plurality of metal layers.

A buffer layer BUF may be disposed on the light blocking layer BSM. The buffer layer BUF may block moisture or impurities from being introduced through the first substrate SUBS1. The buffer layer BUF may be made of silicon oxide (SiOₓ), silicon nitride (SiNₓ), or a plurality of insulating layers.

The driving transistor DT including the active layer ACT, a gate electrode GE, a source electrode SE, and a drain electrode DE may be disposed on the buffer layer BUF.

The active layer ACT may be made of a semiconductor material such as oxide semiconductor, amorphous silicon, or polysilicon, but is not limited thereto. A gate insulating layer GI electrically insulates the active layer ACT from the gate electrode GE of the driving transistor DT. The gate insulating layer GI may be made of silicon oxide (SiOₓ), silicon nitride (SiNₓ), or a plurality of insulating layers.

A pattern of the second metal layer may be disposed on the gate insulating layer GI. The pattern of the second metal layer may include the gate electrode GE of the driving transistor DT. The second metal layer may be made of copper (Cu), aluminum (Al), molybdenum (Mo), nickel (Ni), titanium (Ti), chromium (Cr), or a plurality of metal layers.

A first interlayer insulating layer ILD1 and a second interlayer insulating layer ILD2 are disposed on the gate electrode GE. The first interlayer insulating layer ILD1 and the second interlayer insulating layer ILD2 have contact holes for connecting each of the source electrode SE and drain electrode DE of the driving transistor DD to the active layer ACT. Each of the first interlayer insulating layer ILD1 and the second interlayer insulating layer ILD2 may be made of silicon oxide (SiOₓ), silicon nitride (SiNₓ), or a plurality of insulating layers.

A pattern of a third metal layer may be disposed on the second interlayer insulating layer ILD2. A pattern of the third metal layer may include the source electrode SE and the drain electrode DE connected to the active layer ACT through the contact holes overlapping the active layer ACT and passing through the interlayer insulating layers ILD1 and ILD2. The source electrode SE may be connected to the capacitors C1 and C2 and a first electrode E1 of the light emitting element ED. The third metal layer may be made of copper (Cu), aluminum (Al), molybdenum (Mo), nickel (Ni), titanium (Ti), chromium (Cr), or a plurality of metal layers.

The first capacitor C1 includes a first capacitor electrode C1a and a second capacitor electrode C1b. The first capacitor electrode C1a may be formed in a pattern of the second metal layer disposed on the gate insulating layer GI. The second capacitor electrode C1b is formed in a pattern of a fourth metal layer disposed on the first interlayer insulating layer ILD1 and overlaps the first capacitor electrode C1a with the first interlayer insulating layer ILD1 interposed therebetween. The second capacitor electrode C1b may be connected to the source electrode SE of the driving transistor DT. The fourth metal layer may be made of copper (Cu), aluminum (Al), molybdenum (Mo), nickel (Ni), titanium (Ti), chromium (Cr), or a plurality of metal layers.

The second capacitor C2 includes a third capacitor electrode C2a overlapping the first capacitor electrode C1a with the buffer layer BUF and the gate insulating layer GI interposed therebetween. The third capacitor electrode C2a may be formed in the pattern of the first metal layer disposed on the first substrate SUBS1.

Since the second capacitor C2 is electrically connected between the source electrode SE of the driving transistor DT and the light emitting element ED to increase a capacitance of the light emitting element ED, the brightness can be increased when the light emitting element ED emits light.

A first passivation layer PAS1 covers the pattern of the third metal layer and the second interlayer insulating layer ILD2. The first passivation layer PAS1 may be made of silicon oxide (SiOₓ), silicon nitride (SiNₓ), or a plurality of insulating layers.

A first planarization layer PLN1 is disposed on the first passivation layer PAS1. The first planarization layer PLN1 covers the first passivation layer PAS1 and planarizes a surface on which the light emitting element is disposed. The first planarization layer PLN1 may be a thick single organic insulating layer or a plurality of organic insulating layers made of benzocyclobutene or an acryl-based organic material.

A pattern of a fifth metal layer may be disposed on the first planarization layer PLN1. The pattern of the fifth metal layer may include a reflective layer RF. The reflective layer RF can increase light efficiency by reflecting light from the light emitting element ED toward the front surface of the display panel 100 and can be used as an electrode connecting the light emitting element ED to the pixel circuit or power line. The reflective layer RF may be electrically connected to the source electrode SE of the driving transistor DT and the first capacitor C1 through a contact hole CH1 passing through the first planarization layer PLN1 and the first passivation layer PAS1. In addition, the reflective layer RF may be electrically connected to the first electrode E1 of the light emitting element ED through a first connection electrode CE1 or may electrically connect a second electrode E2 of the light emitting element ED to the high-potential power line VL1. The fifth metal layer may be made of silver (Ag), aluminum (Al), molybdenum (Mo), titanium (Ti), a transparent electrode material such as indium tin oxide (ITO), or a plurality of metal layers.

The second passivation layer PAS2 covers the pattern of the fifth metal layer and the first planarization layer PLN1. The second passivation layer PAS2 may be made of silicon oxide (SiOₓ), silicon nitride (SiNₓ), or a plurality of insulating layers.

An adhesive layer AD may be disposed on the second passivation layer PAS2 to fix the light emitting element ED. The adhesive layer AD may be made of a photocurable resin which may be cured by light. The adhesive layer AD may be made of an acrylic-based material containing a photosensitive agent, but is not limited thereto. The adhesive layer AD may be formed on the front surface of the first substrate SUBS1 excluding the pad areas PA1 and PA2 in which the first pad electrode PAD1 are disposed.

The light emitting element ED of each of the sub-pixels SP may be disposed on the adhesive layer AD. The light emitting elements ED may emit light by a current from the driving transistor DT. The light emitting elements ED may include a red light emitting element ED, a green light emitting element ED, and a blue light emitting element ED. The light emitting element ED may be an LED or micro-LED.

Each of the light emitting elements ED includes a first semiconductor pattern SEM1, a light emitting layer EM, a second semiconductor pattern SEM2, the first electrode E1, and the second electrode E2.

The first semiconductor pattern SEM1 is disposed on the adhesive layer AD, and the second semiconductor pattern SEM2 is disposed on the first semiconductor pattern SEM1. The first semiconductor pattern SEM1 and the second semiconductor pattern SEM2 may be formed as semiconductor patterns obtained by doping n-type and p-type impurities into a semiconductor material. For example, each of the first semiconductor pattern SEM1 and the second semiconductor pattern SEM2 may be a layer obtained by doping the n-type or p-type impurities into a material such as gallium nitride (GaN), indium aluminum phosphide (InAlP), and gallium arsenide (GaAs). In addition, the p-type impurity may be magnesium, zinc (Zn), beryllium (Be), or the like, and the n-type impurity may be silicon (Si), germanium, tin (Sn), or the like, however, the present invention is not limited thereto.

The light emitting layer EM is disposed between the first semiconductor pattern SEM1 and the second semiconductor pattern SEM2. The light emitting layer EM may receive holes and electrons from the first semiconductor pattern SEM1 and the second semiconductor pattern SEM2 and emit light. The light emitting layer EM may be formed in a single-layer or multi-quantum well (MQW) structure and made of, for example, indium gallium nitride (InGaN) or gallium nitride (GaN).

The first electrode E1 is disposed on the first semiconductor pattern SEM1. The first electrode E1 electrically connects the driving transistor DT to the first semiconductor pattern SEM1. The first semiconductor pattern SEM1 may be formed of a semiconductor layer doped with n-type impurities. The first electrode E1 may be an anode of the light emitting element ED disposed on the first semiconductor pattern SEM1 and electrically connected to the driving transistor DT and the capacitors C1 and C2 via the reflective layer RF. The first electrode E1 may be disposed on an upper surface of the first semiconductor pattern SEM1. The first electrode E1 may be made of a conductive material, for example, a transparent conductive material such as ITO or indium zinc oxide (IZO), an opaque conductive material such as titanium (Ti), gold (Au), silver (Ag), copper (Cu), an alloy thereof, or the like.

The second electrode E2 is disposed on the second semiconductor pattern SEM2. The second electrode E2 electrically connects the high-potential power line VL1 to the second semiconductor layer SEM2. The second semiconductor layer SEM2 may be formed as a semiconductor layer doped with p-type impurities. The second electrode E2 may be a cathode of the light emitting element ED. The second electrode E2 may be made of a conductive material, for example, a transparent conductive material such as ITO or IZO, an opaque conductive material such as titanium (Ti), gold (Au), silver (Ag), copper (Cu), an alloy thereof, or the like.

The light emitting element ED may include an encapsulation layer ENS. The encapsulation layer ENS covers the semiconductor patterns SEM1 and SEM2 and the electrodes E1 and E2 and protects the light emitting element ED. The encapsulation layer ENS and a third planarization layer PLN3 include contact holes exposing the first electrode E1 and the second electrode E2. The first connection electrode CE1 is connected to the reflective layer RE through a first contact hole passing through the encapsulation layer ENS and the third planarization layer PLN3. The second connection electrode CE2 is connected to the second electrode E2 through a second contact hole passing through the encapsulation layer ENS and the third planarization layer PLN3. Meanwhile, a portion of a side surface of the first semiconductor pattern SEM1 may be exposed due to no encapsulation layer ENS.

The second planarization layer PLN2 and the third planarization layer PLN3 may cover the adhesive layer AD and the light emitting element ED. The second planarization layer PLN2 comes into contact with a lower end of a side surface of the light emitting element ED and fixes the light emitting element ED. The third planarization layer PLN3 covers the light emitting element ED above the second planarization layer PLN2. The third planarization layer PLN3 includes contact holes exposing the first electrode E1 and the second electrode E2 of the light emitting element ED. The second planarization layer PLN2 and the third planarization layer PLN3 may be made of a single-layer organic insulating material or a plurality of organic insulating materials, such as a photoresist or acryl-based organic material.

A pattern of a sixth metal layer may be disposed on the third planarization layer PLN3. The sixth metal layer may include the first connection electrode CE1 and the second connection electrode CE2. The first connection electrode CE1 electrically connects the first electrode E1 of the light emitting element ED to the reflective layer RF. The first connection electrode CE1 may be connected to the first electrode E1 of the light emitting element ED through a contact hole passing through the insulating layers PLN3 and ENS and connected to the reflective layer RF through a contact hole passing through the insulating layers PAS2, AD, PLN2, and PLN3.

The second connection electrode CE2 is connected to the second electrode E2 of the light emitting element ED through the contact hole passing through the insulating layers PLN3 and ENS. The second connection electrode CE2 may be connected to the low-potential power line VL2.

A bank pattern BB may be disposed on the second planarization layer PLN2. The bank pattern BB may be spaced a predetermined distance from the light emitting element ED. The bank pattern BB may cover a portion of the first connection electrode CE1 which is present in the contact hole passing through the insulating layers PLN2 and PLN3. The bank pattern BB can reduce color mixing between the sub-pixels SP by preventing optical crosstalk between the sub-pixels SP. To this end, the bank pattern BB may be made of a black resin, but is not limited thereto.

A first protective layer CPA may cover the patterns CE1 and CE2 of the sixth metal layer, the bank pattern BB, the second planarization layer PLN2, and the third planarization layer PLN3. The first protective layer CPA may be formed of a single insulating layer made of a translucent epoxy, silicon oxide (SiOₓ), or silicon nitride (SiNₓ), a plurality of insulating layers, or the like.

Each of the first pad electrodes PAD1 disposed on the pad areas PA1 and PA2 of the first substrate SUBS1 may have a structure of a plurality of metal layers. For example, each of the first pad electrodes PAD1 may include a first pad metal layer PE1a, a second pad metal layer PE1b, and a third pad metal layer PE1c stacked on the front surface of the outermost portion of the first substrate SUBS1.

The pattern of the third metal layer disposed on the second interlayer insulating layer ILD2 may further include the first pad metal layer PE1a. The first pad metal layer PE1a may be made of the same metal as that of the source electrode SE and the drain electrode DE of the driving transistor DT, such as copper (Cu), aluminum (Al), molybdenum (Mo), nickel (Ni), titanium (Ti), chromium (Cr), or a plurality of metal layers.

The pattern of the fifth metal layer disposed on the first planarization layer PLN1 may further include the second pad metal layer PE1b. The second pad metal layer PE1b may be made of the same metal as that of the reflective layer RF, such as silver (Ag), aluminum (Al), molybdenum (Mo), or a plurality of metal layers.

The pattern of the sixth metal layer disposed on the third planarization layer PLN3 may further include the third pad metal layer PE1c. The third pad metal layer PE1c may be made of the same conductive material as those of the first connection electrode CE1 and the second connection electrode CE2, for example, a transparent conductive material such as ITO or IZO, or a plurality of metal layers or the like.

A first metal layer ML1, a second metal layer ML2, and a plurality of insulating layers may be disposed under the first pad electrodes PAD1. A step difference of the first pad electrode PAD1 may be adjusted by arranging the first metal layer ML1, the second metal layer ML2, and the plurality of insulating layers under the first pad electrode PAD1. For example, the buffer layer BUF, the gate insulating layer GI, the first metal layer ML1, the first interlayer insulating layer ILD1, and the second interlayer insulating layer ILD2 may be sequentially disposed between the first pad electrode PAD1 and the first substrate SUBS1. The pattern of the second metal layer disposed on the gate insulating layer GI may include the first metal layer ML1. The pattern of the fourth metal layer disposed on the first interlayer insulating layer ILD1 may include the second metal layer ML2. The plurality of insulating layers and metal layers ML2 and ML3 under the first pad electrodes PAD1 are not limited to those of FIG. 6.

The second substrate SUBS2 may be disposed on the rear surface of the first substrate SUBS1. A bonding layer BDL is disposed between the first substrate SUBS1 and the second substrate SUBS2. The bonding layer BDL is cured through various curing methods to bond the first substrate SUBS1 and the second substrate SUBS2. The bonding layer BDL may be disposed only on a partial area between the first substrate SUBS1 and the second substrate SUBS2 or disposed on the entire area. The first substrate SUBS1 and the second substrate SUBS2 may be scribed and ground at the same time so that the side surfaces of the first substrate SUBS1 and the second substrate SUBS2 may be formed as side surfaces without any step.

A plurality of second pad electrodes PAD2 may be disposed on a rear surface of an outermost portion of the second substrate SUBS2. The second pad electrodes PAD2 are electrically connected to the side lines SRL and the first pad electrode PAD1 to transmit signals from circuit components disposed on the rear surface of the second substrate SUBS2 to the sub-pixels SP disposed on the upper surface of the first substrate SUBS1.

Each of the second pad electrodes PAD2 may have a structure of a plurality of metal layers. For example, each of the second pad electrodes PAD2 may include a first pad metal layer PE2a, a second pad metal layer PE2b, and a third pad metal layer PE2c stacked on the rear surface of the outermost portion of the second substrate SUBS2. Each of the first and second pad metal layers PE2a and PE2b may be made of copper (Cu), aluminum (Al), molybdenum (Mo), nickel (Ni), titanium (Ti), chromium (Cr), or a plurality of metal layers. The third pad metal layer PE2c may be made of a transparent conductive material such as ITO or IZO.

A second protective layer BCL may be disposed on the rear surface of the second substrate SUBS2. The second protective layer BCL may cover various lines except for the second pad electrodes PAD2 on the rear surface of the second substrate SUBS2. The second protective layer BCL may be made of an organic insulating material, for example, benzocyclobutene or an acryl-based organic insulating material.

Circuit components such as a plurality of flexible films and a PCB may be disposed on the rear surface side of the second substrate SUBS2. Output terminals of the flexible film are electrically connected to the second pad electrode PAD2, and input terminals of the flexible film are electrically connected to output terminals of the PCB. Therefore, the signals or voltages output from the PCB may be transmitted to the sub-pixels SP disposed on the front surface of the first substrate SUBS1 through the flexible film, the second pad electrode PAD2, the side line SRL, the plurality of first pad electrodes PAD1, and the lines connected to the first pad electrode PAD1.

The side lines SRL electrically connect the first pad electrodes PAD1 to the second pad electrodes PAD2 across the side surfaces of the first substrate SUBS1 and the second substrate SUBS2. The side lines SRL may be formed on the side surfaces of the substrates SUBS1 and SUBS2 in a pad printing method using conductive ink, for example, conductive ink containing silver (Ag), copper (Cu), molybdenum (Mo), chromium (Cr), or the like.

A side insulating layer SDI may cover the side lines SRL formed on the upper, side, and rear surfaces of the outermost portions of the bonded substrates SUBS1 and SUBS2. When the side lines SRL are made of a metal, external light may be reflected from the side lines SRL, or light emitted from the light emitting element ED may be reflected from the side lines SRL to be visible to the user. In order to suppress the degradation in image quality due to reflected light, the side insulating layer SDI may include a black material for absorbing external light. For example, the side insulating layer SDI may be formed on the outermost portions of the substrates SUBS1 and SUBS2 with black ink which can be applied in a printing method.

A seal SS may cover the side insulating layer SDI to protect the display panel 100 from an external impact, moisture, oxygen, or the like. For example, the seal SS may be made of polyimide (PI), polyurethane, epoxy, or acryl-based insulating material or the like.

A functional film MF may cover the front surface of the first display panel 100. The functional film MF may be one or more among various functional films such as an anti-shattering film, an anti-glare film, an anti-reflecting film, a low-reflecting film, an OLED transmittance controllable film, a color difference compensation film, and a polarizer. The anti-shattering film prevents pieces or particles of the substrate from shattering when the display panel 100 is broken. The functional film MF may be removed by being cut together with an outer portion of the seal SS along a cutting line overlapping with the seal SS after the seal SS is widely bonded to the front surface of the first substrate SUBS1. As a result, the side surfaces exposed at the outermost portions of the functional film MF and the seal SS may form the side surfaces on the same plane without any step.

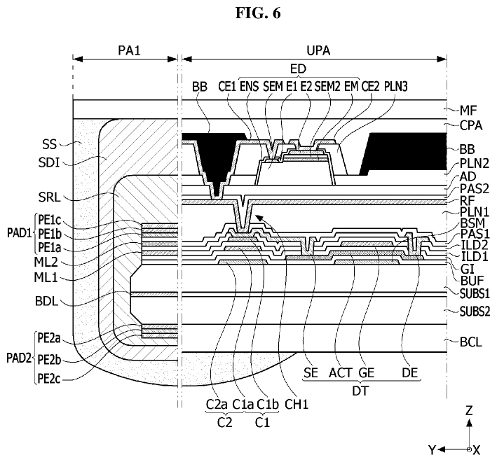

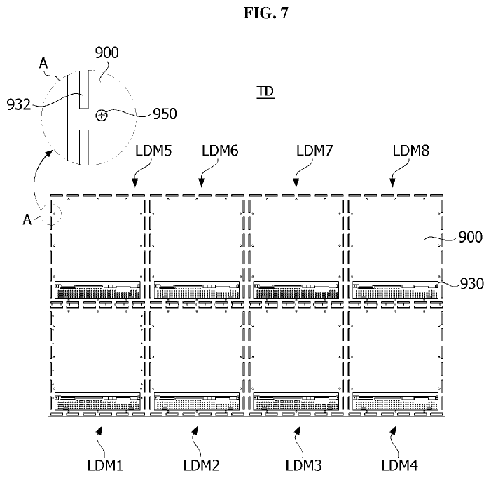

FIG. 7 is a plan view showing a tiling frame to which a plurality of display modules are coupled according to one embodiment of the present disclosure.

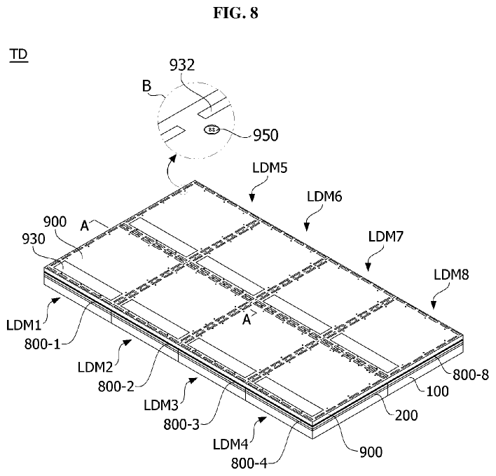

FIG. 8 is a perspective view showing the tiling frame to which the plurality of display modules are coupled according to one embodiment of the present disclosure. In FIGS. 7 and 8, dotted line circles show an enlarged view of portion “B.”

Referring to FIGS. 7 and 8, the tiling display device TD according to one embodiment of the present disclosure includes a plurality of display modules LDM1 to LDM8.

The tiling display device TD includes the plurality of display modules LDM1 to LDM8 and a tiling frame 900. The tiling display device TD implements a large screen by connecting screens of the plurality of display modules LDM1 to LDM8 on the same plane.

Meanwhile, since the tiling display device TD has a very large size, it is difficult to transport the tiling display device TD to an installation site in a state in which the plurality of display modules LDM1 to LDM8 are connected. Therefore, after the plurality of display modules LDM1 to LDM8 are transported to the installation site, the plurality of display modules LDM1 to LDM8 may be fastened to the tiling frame 900 at the installation site.

In this case, the plurality of display modules LDM1 to LDM8 may be attached as close as possible so that distances between the plurality of display modules LDM1 to LDM8 are constant and minimized to allow the plurality of display modules LDM1 to LDM8 to be shown as one display device. In other words, by precisely aligning and attaching the plurality of display modules LDM1 to LDM8 to the tiling frame 900, it is possible to minimize a border area where images are not displayed.

Referring to FIGS. 7 and 8, the tiling display device TD according to one embodiment of the present specification may include the plurality of display modules LDM1, LDM2, LDM3, LDM4, LDM5, LDM6, LDM7, and LDM8, a plurality of module frames 800-1, 800-2, 800-3, 800-4, 800-5, 800-6, 800-7, and 800-8 respectively coupled to rear surfaces of the display modules LDM1 to LDM8, the tiling frame 900 to which the plurality of module frames 800-1 to 800-8 to which the plurality of display modules are coupled, respectively, are coupled, and a screw 950, which is a fastening member for coupling the plurality of module frames 800-1 to 800-8 to the tiling frame 900 to be replaced.

Each of the plurality of display modules LDM1, LDM2, LDM3, LDM4, LDM5, LDM6, LDM7, and LDM8 is disposed in the form of N×M (N is a positive integer of 2 or more, and M is a positive integer of 2 or more) to display individual images or dividedly display one image. Here, although a case in which the plurality of display modules LDM1, LDM2, LDM3, LDM4, LDM5, LDM6, LDM7, and LDM8 are disposed in the form of 4×2 is described as an example, the present invention is not limited thereto and can be applied to various embodiments.

Since each of the plurality of display modules LDM1, LDM2, LDM3, LDM4, LDM5, LDM6, LDM7, and LDM8 includes the display module according to the present specification shown in FIGS. 1 to 6, overlapping descriptions thereof will be omitted.

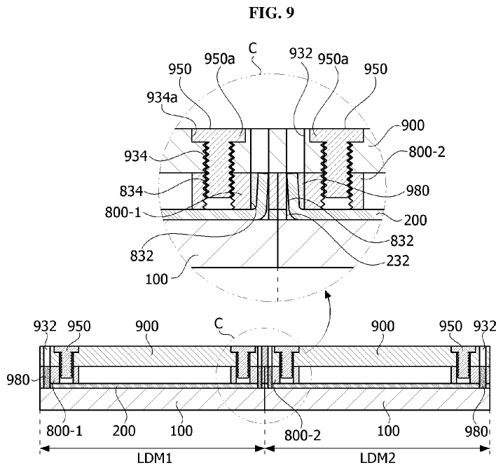

FIG. 9 is a cross-sectional view of the display device along line A-A′ in FIG. 8, which is a combined cross-sectional view showing a portion in which a module frame coupled to each of the display modules is coupled to the tiling frame by a screw in the display device according to one embodiment of the present disclosure. In FIG. 9, a dotted line circle show an enlarged view of portion “C.”

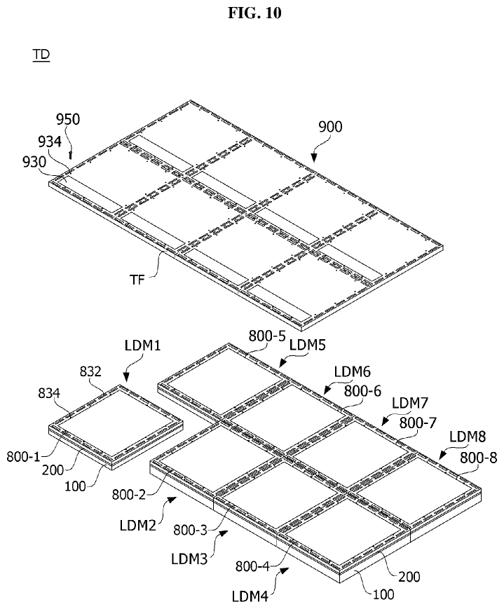

FIG. 10 is an exploded perspective view showing one example in which a plurality of display modules are disassembled from the tiling frame, and a defective display module among the plurality of display modules is disassembled the according to one embodiment of the present disclosure.

Referring to FIGS. 9 and 10, the plurality of module frames 800-1, 800-2, 800-3, 800-4, 800-5, 800-6, 800-7, and 800-8 may be coupled one-to-one to the display modules LDM1, LDM2, LDM3, LDM4, LDM5, LDM6, LDM7, and LDM8 and may support the corresponding display module. In FIG. 9, although a structure in which the plurality of display modules LDM1 and LDM2 are coupled to a portion of the tiling display device, that is, a front surface of the tiling frame 900 is described as an example, but the present invention is not limited thereto.

The plurality of display modules LDM1 to LDM8 may be coupled using a resin which fills a first opening 232 formed in the cover bottom 200 attached to the rear surface thereof and a second opening 832 formed in the rear surface of each of the plurality of module frames 800-1, 800-2, 800-3, 800-4, 800-5, 800-6, 800-7, and 800-8.

In addition, each of the module frames 800-1 to 800-8 may be disposed on the rear surface of each of the plurality of display modules LDM1 to LDM8. The module frames 800-1 to 800-8 according to one example may each include a shape having a size corresponding to each of the display modules LDM1 to LDM8.

The plurality of module frames 800-1 to 800-8 are configured in a quadrangular frame shape and are open at the top and bottom. A plurality of second openings 832 and first fastening holes 834 are formed at regular distances on a front surface of the quadrangular frame shape.

By filling the first openings 232 formed in the cover bottom 200, which are correspondingly positioned under the plurality of second openings 832, with the resin 980, each of the display device module frames 800-1 and 800-2 may be fixedly coupled to one of the display modules LDM1 and LDM2. In this case, the resin 980 fills the first openings 232 and the second openings 832 and is thermally cured.

In particular, each of the display module frames 800-1 to 800-8 is fixedly coupled to one of the plurality of display modules LDM1 to LDM8.

In addition, the tiling frame 900 has a second through-hole 930 through which a cable for connecting a driving system (or a main control board) of the multi-display device with the printed circuit board of the display module LDM may pass. The second through-hole 930 may have a circular or polygonal shape.

A plurality of third openings 932 and second fastening holes 934 are formed in an edge of the tiling frame 900 at a regular distance.

Each of the plurality of third openings 932 and the second fastening holes 934 is disposed to correspond to the second opening 832 and the first fastening hole 834 formed in one of the plurality of display module frames 800-1 to 800-8.

In particular, the plurality of third openings 932 and second fastening holes 934 may be formed on the front surface of the tiling frame 900 on which the plurality of module frames 800-1 to 800-8 respectively coupled to the plurality of display modules LDM1 to LDM8 are disposed at regular distances.

Here, the plurality of third openings 932 and second fastening holes 934 may be formed to couple each of the plurality of module frames 800 to the front surface of the tiling frame 900 to be replaced, the number thereof is not limited, and the third openings 932 and the second fastening holes 934 may be formed by adjusting the number thereof as needed.

In particular, each of the plurality of third openings 932 and second fastening holes 934 is formed in the front surface of the tiling frame 900 to correspond to the second opening 832 and the first fastening hole 834 formed in each of the plurality of module frames 800-1 to 800-8. In other words, the plurality of third openings 932 may correspond to the second openings 832 of the module frames 800-1 and 800-2, which are positioned thereunder, and the second fastening holes 934 may be formed to correspond to the first fastening holes 834 of the display device module frames 800-1 and 800-2, which are positioned thereunder.

By supplying the resin 980 to the third openings 932 and filling and then fixedly curing the resin 980 between the second protrusions 233 bent from the cover bottoms 200 and the second openings 832 of the module frames 800-1 and 800-2, each of the display modules LDM1 and LDM2 may be fixedly coupled to one of the module frames 800-1 and 800-2.

In this case, since the resin 980 does not fill the first opening 232 of the cover bottom 200 and fills only between the second protrusion 233 and the second opening 832, each of the display modules LDM1 and LDM2 may be fixedly coupled to one of the module frames 800-1 and 800-2.

In addition, since a fastening member, for example, the screw 950 is inserted into the second fastening hole 934, and the screw 950 is fastened to the first fastening hole 834 correspondingly disposed under the second fastening hole 934, the module frames 800-1 and 800-2 to which the display modules LDM1 and LDM2 are respectively coupled are fastened to the front surface of the tiling frame 900 to be replaced.

As described above, the module frames 800-1 to 800-8 to which the plurality of display modules LDM1 to LDM8 are respectively coupled are coupled by being fastened to the front surface of the tiling frame 900 by the plurality of screws 950 to constitute the tiling display device TD according to the present embodiment.

In other words, since each of the plurality of display modules LDM1 to LDM8 is independently disposed and coupled to the front surface of the tiling frame 900 by the plurality of module frames 800-1 to 800-8 to be replaced, whenever a defect occurs, only a defective display module LDM1 among the plurality of display modules LDM1 to LDM8 may be replaced by rotating counterclockwise and individually separating the screw 950 from the tiling frame 900.

Meanwhile, referring to FIG. 10, a display device according to another embodiment of the present specification may include N display modules LDM1 to LDM8 (N is a natural number of 2 or more) and a frame to which each of the display modules LDM1 to LDM8 is fastened to be replaceable.

The frame may include the tiling frame 900 for supporting one surface of each of the N display modules LDM1 to LDM8 so that the N display modules LDM1 to LDM8 are disposed on the same plane, and the plurality of module frames 800-1 to 800-8 for supporting the one surface of each of the M display modules LDM1 to LDM8 (M is a natural number greater than 0 and smaller than N).

Each of the module frames 800-1 to 800-8 may be interposed between one of the display modules LDM1 to LDM8 corresponding thereto and the tiling frame 900, and each of the module frames 800-1 to 800-8 may be fastened to the tiling frame 900 to be replaced.

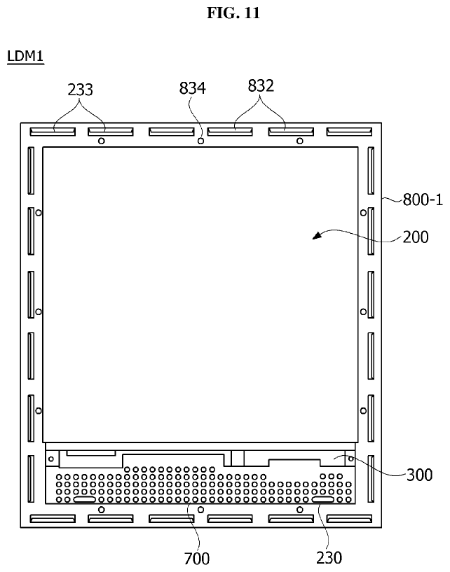

FIG. 11 is a plan view showing the module frame to which the display module is coupled in the display device according to one embodiment of the present disclosure.

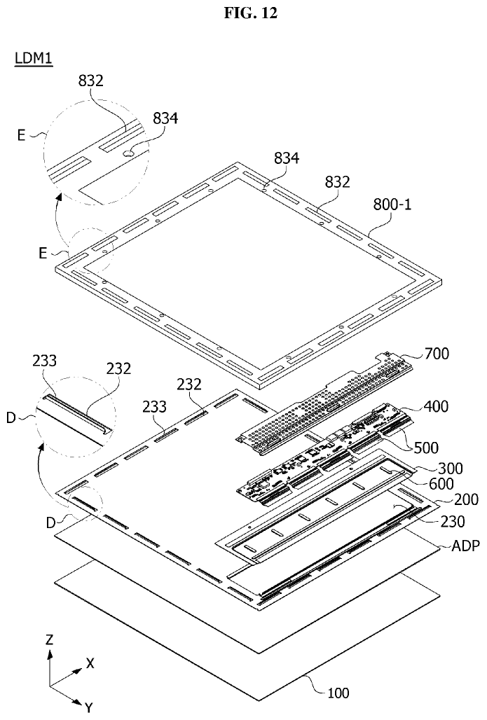

FIG. 12 is an exploded perspective view showing the display module and the module frame in the display device according to one embodiment of the present disclosure. In FIG. 12, dotted line circles show enlarged views of portions “D” and “E.”

The display module LDM1 according to the embodiment shown in FIGS. 11 and 12 may include the display panel 100 including the front surface on which an image is displayed and the rear surface opposite to the front surface, the cover bottom 200 disposed on the rear surface of the display panel 100, and the module frame 800-1 coupled to a rear surface of the cover bottom 200.

In addition, the display module LDM1 according to the embodiment may include a plate bottom 300 disposed in contact with the display panel 100 in a first through-hole 230 of the cover bottom 200, at least one flexible film 500 for connecting the display panel 100 with a circuit board 400 through the first through-hole 230 of the cover bottom 200, and at least one rib 600 disposed between the plate bottom 300 and the circuit board 400.

In addition, the display module LDM1 according to the embodiment may include a cover shield 700 for covering the circuit board 400.

In addition, the display module LDM1 according to the embodiment may include a gasket (not shown) disposed between the circuit board 400 and the cover shield 700 for grounding. Here, the flexible film 500 may be a chip on film (COF) on which an IC in which circuits of the data driver DD and/or the gate driver GD are integrated is mounted.

Referring to FIG. 12, a significant amount of heat may be generated from the flexible film 500 due to the IC. In addition, since the second pad electrodes PAD2 and the plurality of lines, which are made of a metal material, are densely disposed on one area of the rear surface of the display panel 100 to which the flexible film 500 is connected, a high heat source area (not shown) may be formed near the second pad electrodes PAD2 (see FIG. 6).

The display device according to the embodiment of the present specification can reduce a temperature difference between the high heat source area and other areas of the display panel 100 by discharging heat to the outside using the plate bottom 300. In this case, the display device according to the embodiment of the present specification may quickly discharge heat generated from the high heat source area to the outside using the plate bottom 300 made of a different material with higher thermal conductivity than the cover bottom 200.

In addition, the display panel 100, the cover bottom 200, the plate bottom 300, and the cover shield 700 may form the exterior of the display module LDM1 according to the embodiment, and the module cover member may include the cover bottom 200, the plate bottom 300, and the cover shield 700.

The display panel 100 may be formed in a plate shape with a predetermined thickness and may include the front surface on which images are implemented and the rear surface opposite to the front surface. Here, the rear surface may be one surface of the display panel 100 disposed at the top with respect to the Z direction in the drawing. In addition, the front surface of the display panel 100 may be referred to as a first panel surface, and the rear surface of the display panel 100 may be referred to as a second panel surface.

In addition, the display panel 100 may be electrically connected to the circuit board 400 using the flexible film 500.

The adhesive member ADP is disposed between the cover bottom 200 and the display panel 100. The adhesive member ADP may be made of an adhesive material to fix the cover bottom 200 to the rear surface of the display panel 100. The adhesive member ADP may be disposed along the edge of the display panel 100 and an edge of the cover bottom 200. The adhesive member ADP may be formed in a frame shape corresponding to the edge of the display panel 100. For example, the adhesive member ADP may be an adhesive foam tape, but is not limited thereto.

The adhesive member ADP may be disposed adjacent to the edge of the cover bottom 200.

In addition, the cover bottom 200 may support and protect the display panel 100 on the rear surface of the display panel 100. The cover bottom 200 may have a shape corresponding to a planar shape of the display panel 100 and cover the display panel 100. The cover bottom 200 may be made of a material, which has rigidity and high thermal conductivity and made of a metal material such as aluminum (Al), copper (Cu), zinc (Zn), silver (Ag), gold (Au), iron (Fe), a stainless steel, or Invar, or a material such as plastic.

The cover bottom 200 includes the first through-hole 230 and the plurality of openings 232.

The first through-holes 230 of the cover bottom 200 are formed to correspond to the plurality of flexible films 500 and the printed circuit board 400. The first through-holes 230 may be positioned in an area in which the plurality of flexible films 500 are bonded to the display panel 100. For example, the flexible film 500 may be bonded to an area adjacent to an edge of one side of the display panel 100, and the first through-hole 230 may also be formed to correspond to the area adjacent to the edge of the one side of the display panel 100.

In addition, the flexible film 500 and the printed circuit board 400 may pass through the first through-hole 230 and may be disposed on the rear surface of the cover bottom 200. Therefore, the plurality of flexible films 500 and the printed circuit board 400 may be disposed on the cover bottom 200 without separately providing the area where the plurality of flexible films 500 and the printed circuit board 400 are disposed between the cover bottom 200 and the display panel 100. In this case, the plate bottom 300 may be seated in the first through-hole 230 of the cover bottom 200 to support the printed circuit board 400, and detailed descriptions thereof will be made below.

A first protrusion 230a is formed at the edge of the first through-hole 230. The first protrusion 230a may be disposed at one side of the edge of the first through-hole 230 adjacent to an edge of one side of the display panel 100. The first protrusion 230a may be disposed to protrude from the edge of the one side of the first through-hole 230 in a direction perpendicular to the rear surface of the cover bottom 200. The first protrusion 230a may be engaged with the cover shield 700 to be described below to restrict the movement of the cover shield 700 and guide a position of the cover shield 700.

The plurality of first openings 232 of the cover bottom 200 are formed along an edge portion of the cover bottom 200. The plurality of first openings 232 may be formed parallel to the edge portion of the cover bottom 200. The plurality of first openings 232 are openings formed together with the plurality of protrusions 233.

In a state in which the module frame 800-1 is disposed on the rear surface of the cover bottom 200, since each of a plurality of second protrusions 233 of the cover bottom 200 is fitted into each of the plurality of second openings 832 formed along an edge portion of the module frame 800-1, it is possible to prevent the module frame 800-1 from being separated from the cover bottom 200.

In addition, since the resin 980 (see FIG. 9) fills a space between the plurality of first openings 232 in contact with the plurality of second protrusions 233 and the plurality of second openings 832 formed along the edge portion of the module frame 800-1 corresponding thereto so that the module frame 800-1 is fixedly coupled to the rear surface of the cover bottom 200, the display module LDM1 may be coupled to the tiling frame 900 in a form of a tile by the module frame 800-1 to be replaced.

In particular, each of the plurality of display modules LDM1 to LDM8 may be coupled to the tiling frame 900 in the form of a tile in a state of being independently coupled to the module frames 800-1 to 800-8, and when at least one display panel 100 to be replaced due to a defect or damage among the plurality of display modules LDM1 to LDM8 is replaced, the display panel 100 may be easily disassembled from the tiling frame 900 by rotating the fastening member, for example, the screw 950 fastened to the display device module frame 800-1 coupled to the rear surface of the display module LDM1 and the rear surface of the tiling frame 900 counterclockwise. The fastening member is not limited to the screw 950, and various fastening members can be used.

In other words, the module frames 800-1 to 800-8 respectively coupled to the display modules LDM1 to LDM8 may be coupled to the tiling frame 900 (see FIG. 10) by the screw 950 to form the tiling display device TD.

The plurality of second protrusions 233 are portions bent from edge portions of one sides of the plurality of first openings 232 and protrude onto the rear surface of the cover bottom 200. The plurality of second protrusions 233 are portions in which a portion the cover bottom 200 is bent in a direction perpendicular to the rear surface of the cover bottom 200, and cross-sectional shapes thereof may have an “L” shape.

The second protrusion 233 may be formed by cutting and then bending a portion of the cover bottom 200. Therefore, when the plurality of second protrusions 233 are formed, the plurality of first openings 232 may be formed in the cut portion of the cover bottom 200. Therefore, the second protrusions 233 may be disposed on edge portions of the plurality of first openings 232. For example, the second protrusion 233 may be disposed on an edge portion of the first opening 232 disposed parallel to the edge portion of the cover bottom 200.

Meanwhile, the display panel 100 and the cover bottom 200 may be connected through the adhesive member ADF formed along the edge portion of the cover bottom 200.

The plate bottom 300 is disposed between the printed circuit board 400 and the first through-hole 230 of the cover bottom 200. A portion of the plate bottom 300 may cover an edge portion of the other side of the first through-hole 230 and the cover bottom 200, and the other portion of the plate bottom 300 may be disposed in the first through-hole 230. The plate bottom 300 may pass through the first through-hole 230 to support the printed circuit board 400 disposed on the cover bottom 200. For example, the plate bottom 300 may be disposed in contact with the display panel 100 outside the printed circuit board 400 and spaced apart from the display panel 100 in an area overlapping the printed circuit board 400 to support the printed circuit board 400.

The plate bottom 300 may extend to the outside of the first through-hole 230 and be disposed to overlap the rear surface of the cover bottom 200. For example, the plate bottom 300 may extend from the first through hole 230 toward a central portion of the display panel 100 and be disposed to overlap the rear surface of the cover bottom 200.

In this case, an area where one ends of the plurality of flexible films 500 are bonded to the display panel 100 may be a partial area of the first through-hole 230 not overlapping the plate bottom 300. The one ends of the plurality of flexible films 500 may overlap the first through-hole 230 and be disposed to be spaced apart from the plate bottom 300.

The plate bottom 300 may distributively dissipate the heat generated from the printed circuit board PCB. In addition, the plate bottom 300 can minimize the concentration of the heat generated from the printed circuit board 400 on a specific area of the display panel 100 by preventing the direct contact between the printed circuit board 400 and the display panel 100. Specifically, the printed circuit board 400 may include a plurality of components and some driving chips from which heat is significantly generated among the plurality of components may be disposed thereon. The plate bottom 300 may distribute the heat generated from some driving chips of the printed circuit board 400 to the entirety of the plate bottom 300, thereby preventing heat from being concentrated on some areas of the display panel 100 adjacent to the driving chips and reducing the temperature difference of the entire display panel 100.

The plate bottom 300 includes a bead 600. The bead 600 may be a portion protruding from one surface of the plate bottom 300 toward the printed circuit board 400 and can improve the rigidity of the plate bottom 300 while supporting the printed circuit board 400. The bead 600 may come into direct contact with the printed circuit board 400, and the heat generated from the printed circuit board 400 may be distributed to the entirety of the plate bottom 300 through the bead 600.

Although not shown in the drawing, the plate bottom 300 includes a fastening part (not shown). The fastening part (not shown) is a part to which fasteners (not shown) passing through a first fastening hole (not shown) of the printed circuit board 400 and a second fastening hole (not shown) of the cover shield 700 are coupled. The fastener (not shown) may be coupled to the fastening part to mutually fix the plate bottom 300, the printed circuit board 400, and the cover shield 700.

The cover shield 700 is disposed on the cover bottom 200, the plate bottom 300, and the printed circuit board 400. The cover shield 700 may protect the printed circuit board 400 from an external impact. The cover shield 700 may be made of a rigid material to protect the printed circuit board 400, but is not limited thereto.

The cover shield 700 may be disposed on the rear surface of the cover bottom 200 to cover the printed circuit board 400. An edge portion of one side of the cover shield 700 may be bent toward the cover bottom 200 and be in contact with an outer surface of the first protrusion 230a. For example, the edge portion of the one side of the cover shield 700 may be bent in a “1” shape and be in contact with the outer surface of the first protrusion 230a of the cover bottom 200. Therefore, the first protrusion 230a and the one side portion of the cover shield 700 may be engaged to restrict the movement of the cover shield 700, and a position of the cover shield 700 may be guided.

As described above, the module frame 800-1 has a quadrangular frame shape, is open at the top and bottom, and is configured to be coupled to the cover bottom 200 disposed on the rear surface of the display module LDM1.

The module frame 800-1 is formed with a plurality of second openings 832 and a plurality of first fastening holes 834 at regular distances on a front surface of the quadrangular frame shape.

The plurality of second openings 832 may be formed to correspond to the plurality of first openings 232 of the cover bottom 200, and the second protrusions 233 of the cover bottom 200 may be disposed by being fitted into the second openings 832.

The second protrusion 233 of the cover bottom 200 is inserted from the second opening 832 of the module frame 800 to function to prevent the module frame 800 from being separated from the cover bottom 200 to the left and right sides.

In addition, by filling and thermally curing the resin 980 (see FIG. 9) between the second opening 832 of the module frame 800-1 and the second protrusion 233 cut and bent from the first opening 232 of the cover bottom 200, which is correspondingly positioned thereunder, the module frame 800 is coupled to the rear surface of the cover bottom 200.

In other words, since the resin 980 does not fill the first opening 232 of the cover bottom 200 and fills only between the second protrusion 233 and the second opening 832 and is thermally cured, each of the display modules LDM1 and LDM2 may be fixedly coupled to one of the module frames 800-1 and 800-2.

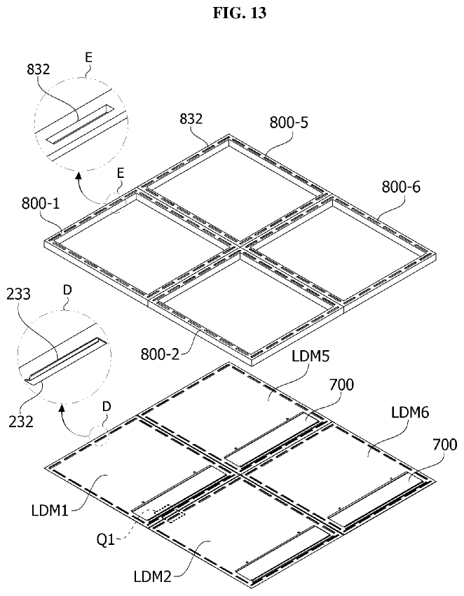

FIG. 13 is a perspective view showing a state in which the plurality of display modules are fixed to the module frames according to one embodiment. In FIG. 13, dotted line circles show enlarged views of portions “D” and “E.”

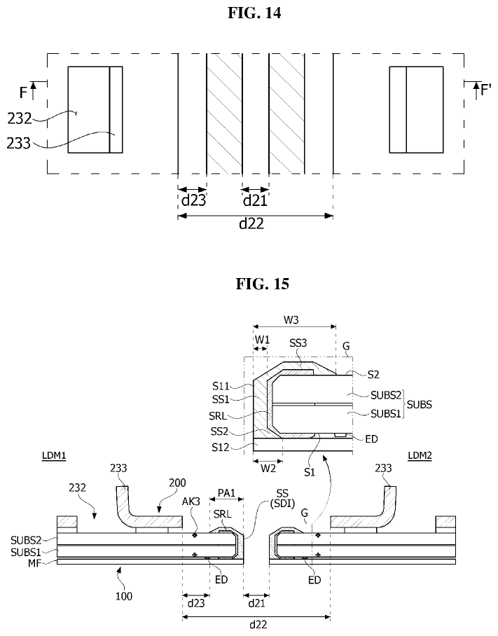

FIG. 14 is an enlarged view of portion Q1 in FIG. 13 according to one embodiment. FIG. 15 is a cross-sectional view of the display module along line F-F′ in FIG. 14 according to one embodiment. In FIG. 15, dotted line circles show an enlarged view of portion “G.”

Referring to FIG. 13, a plurality of display modules LDM1, LDM2, LDM5, and LDM6 can be implemented as a large-screen tiling display device by being coupled. Although FIG. 13 shows an example in which four display modules LDM1, LDM2, LDM5, and LDM6 are coupled to the module frames 800-1, 800-2, 800-5, and 800-6, respectively to form one large screen, the number of display modules is not particularly limited thereto.

The plurality of second protrusions 233 disposed on the plurality of display modules LDM1, LDM2, LDM5, and LDM6 may be fitted into the second openings 832 of the module frames 800-1, 800-2, 800-5, and 800-6, respectively. Thereafter, since the resin 980 fills a space between the second protrusion 233 and the second opening 832 and is thermally cured, the plurality of display modules LDM1, LDM2, LDM5, and LDM6 may be fixed to the module frames 800-1, 800-2, 800-5, and 800-6, respectively.

According to the embodiment, since the plurality of display modules LDM1, LDM2, LDM5, and LDM6 are coupled to the module frames 800-1, 800-2, 800-5, and 800-6 to form the tiling display device, it is necessary to maintain a constant distance between the plurality of display modules LDM1, LDM2, LDM5, and LDM6 for a uniform image, and planarization work may be needed to prevent the formation of a step.

Referring to FIGS. 14 and 15, the display modules may be spaced a predetermined distance in a state of being coupled to the module frames 800-1 and 800-2 (see FIG. 13). When the plurality of display modules are fixed to the module frames 800-1 and 800-2 without any gap, there may be a problem that the boundaries of the plurality of display modules are visible when a step due to an assembly tolerance is formed. Therefore, the plurality of display modules LDM1 and LDM2 disposed adjacent to each other to form the integrated tiling display device may be spaced a predetermined distance from each other.

A first separation distance d21 between the plurality of display modules LDM1 and LDM2 may be in a range of 1 μm to 200 μm. When the separation distance is satisfied, an interference problem due to tolerance or thermal deformation can be solved, and thus a seam area may be invisible. However, the first separation distance d21 is not necessarily limited thereto and may be adjusted in various ways depending on a structure or size of the display panel.

As described above, the first pad electrode may be disposed on an outermost portion of one surface S1 of the display panel 100, and the second pad electrode may be disposed on an outermost portion of the other surface S2. The first pad electrode and the second pad electrode may be electrically connected by the side line SRL. A cover layer SS may be formed on the side line SRL. The cover layer SS may include black ink or an organic/inorganic material layer.

The functional film MF attached to the substrate SUBS may have a side surface parallel to a side surface of the cover layer SS. In other words, a side surface S12 of the functional film MF and a side surface S11 of the cover layer SS may be disposed on the same plane. Therefore, the first separation distance d21 between the cover layers SS in the two adjacent display modules LDM1 and LDM2 may be the same as the separation distance d21 between the functional films MF.

The cover layer SS may include a first area SS1 formed on the side surface of the substrate SUBS, a second area SS2 extending to the one surface S1 of the substrate SUBS, and a third area SS3 connected to the other surface S2 of the substrate SUBS. In this case, a width W3 of the third area SS3 may be larger than a width W2 of the second area SS2. The second area S22 may not cover a portion of the side line SRL formed on the one surface of the substrate SUBS. This is because the cover layer SS is formed after the functional film MF is attached to the one surface of the substrate SUBS on which the side line SRL is formed. The third area SS3 of the cover layer SS may be formed to be sufficiently large to cover the side lines SRL exposed on the other surface of the substrate SUBS.

An area of the cover bottom 200 may be smaller than an area of the display panel 100. Therefore, the cover bottom 200 may not cover the cover layer SS formed on the side surface of the display panel 100. The cover bottom 200 may be spaced a predetermined distance from the cover layer SS. This is because interference with the adjacent display modules LDM1 and LDM2 may occur upon the occurrence of an assembly tolerance or the like when the cover bottom 200 is designed to have the same area as that of the display panel 100.

Therefore, in the neighboring display modules LDM1 and LDM2, a second separation distance d22 between the cover bottoms 200 may be larger than a first separation distance d21 between the cover layers SS.

With this configuration, the cover bottom 2200 may expose an alignment key AK3 for arranging the display panel 100 at the correct position on a jig. Therefore, the alignment key AK3 may be disposed in a separation space S23 between the cover bottom 200 and the seal SS. However, the present invention is not necessarily limited thereto, and the cover bottom 200 may extend to cover the cover layer SS. In this case, a hole for exposing the alignment key AK3 may be formed in the cover bottom 200.

The cover bottom 200 may include a plurality of protrusions 233 to be coupled to the module frame 800-1. The second protrusion 233 may be formed by cutting and then bending a portion of the cover bottom 200. Therefore, the second protrusion 233 may be formed at one side of the first opening 232 formed by cutting the second protrusion 233. However, the present invention is not necessarily limited thereto, and a separate protrusion may be coupled to the cover bottom 200. In other words, various known methods can be applied to form the second protrusion 233.

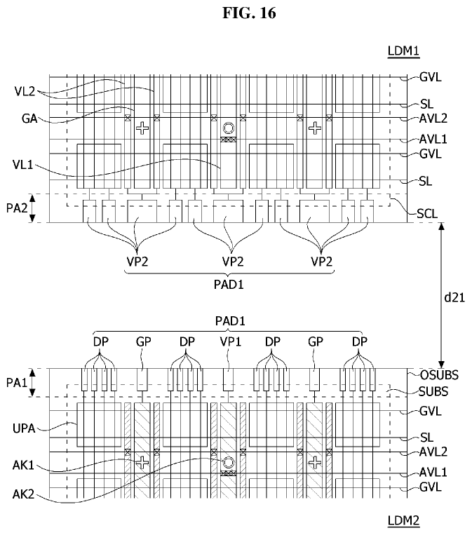

FIG. 16 is a view showing shapes of electrode pads disposed on the display panels of neighboring display modules according to one embodiment.

Referring to FIG. 16, the plurality of display modules may be consecutively disposed in the X-axis and Y-axis directions.

Therefore, shapes of pads in areas in which neighboring first display modules LDM1 and second display modules LDM2 face each other may be different. As described with reference to FIG. 5, the power pads VP1 and VP2 of the display panel 100 may include the plurality of high-potential power pads VP1 disposed on the first pad area PA1 and the plurality of low-potential power pads VP2 disposed on the second pad area PA2. The data pad DP and the gate pad GP may be further disposed on the first pad area PAL.

The data pad DP and the gate pad GP may have relatively smaller widths, and the power pads VP1 and VP2 may have relatively larger widths. In addition, the low-potential power pads VP2 may have larger widths than the high-potential power pads VPL.

Therefore, since the low-potential power pads VP2 disposed on the second pad area PA2 of the first display module LDM1 are disposed to face the high-potential power pads VP1 disposed on the first pad area PA1 of the second display module LDM2, a width of the electrode pad PAD1 disposed on the side surface of the first display module LDM1 may be larger than a width of the electrode pad PAD1 disposed on the side surface of the second display module LDM2 that faces the side surface of the first display module LDM1.

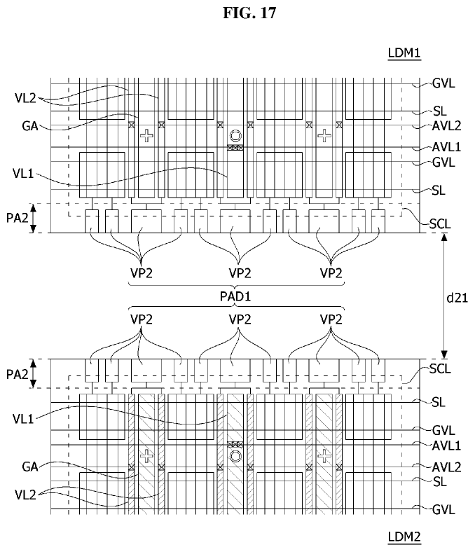

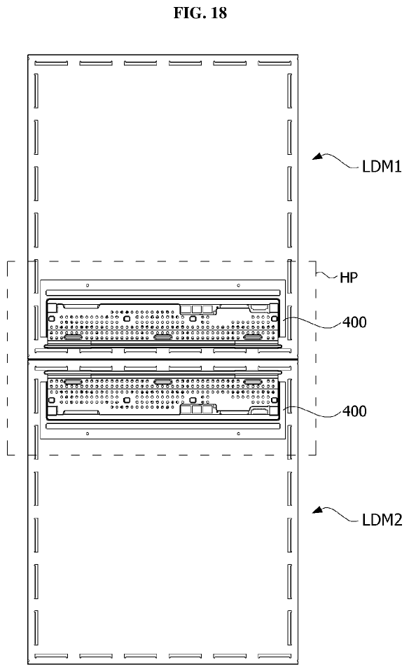

FIG. 17 is a view showing a first modified example of the electrode pads of FIG. 16 according to one embodiment. FIG. 18 is a view showing a state in which two display modules are disposed according to FIG. 17 according to one embodiment.

Referring to FIGS. 17 and 18, the width of the electrode pad PAD1 disposed on the side surface of the first display module LDM1 may be the same as the width of the electrode pad PAD1 disposed on the side surface of the second display module LDM2. In this case, the circuit boards 400 of the first and second display modules LDM1 and LDM2 may be disposed adjacent to each other.

With this arrangement, it is possible to increase heat dissipation efficiency by arranging the circuit boards 400 from which more heat is generated to face each other and forming a heat dissipation structure in a high heat source area HP on which heat is concentrated.

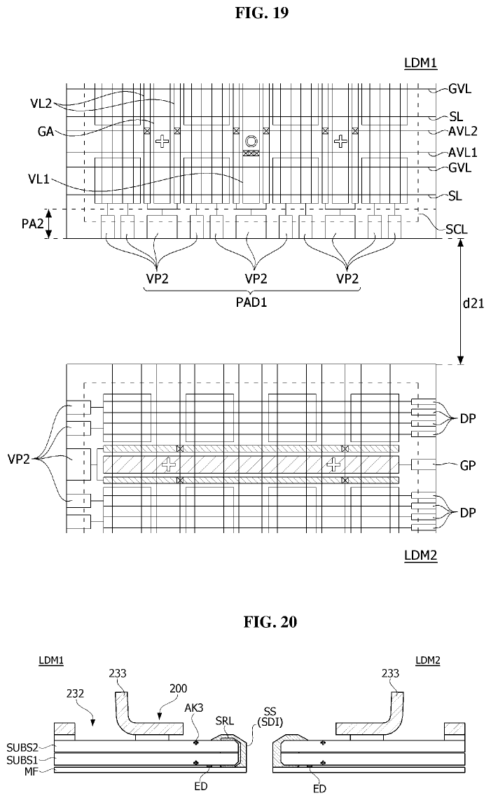

FIG. 19 is a view showing a second modified example of the electrode pads of FIG. 16 according to one embodiment. FIG. 20 is a view showing a cross-sectional structure of two display modules according to FIG. 19 according to one embodiment.

Referring to FIGS. 19 and 20, the electrode pad PAD1 is formed on the side surface of the first display module LDM1, while the electrode pad may not be formed on the side surface of the second display module LDM2 that faces the side surface of the first display module LDM1. Therefore, while the side line SRL is formed on the side surface of the first display module LDM1, the side line may not be formed on the side surface of the second display module LDM2 that faces the side surface of the first display module LDM1. According to the embodiment, since the plurality of display modules are manufactured by being tiled, the display modules may be coupled by being rotated in different directions due to various issues (light uniformity and the like).

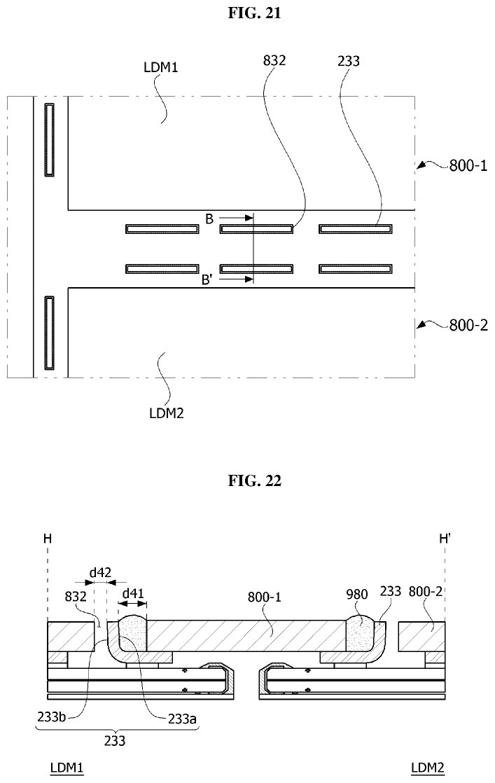

FIG. 21 is a plan view showing a state in which a plurality of display modules are coupled to a module frame according to one embodiment. FIG. 22 is a cross-sectional view of the display modules along line H-H′ in FIG. 21 according to one embodiment.

Referring to FIGS. 21 and 22, the plurality of second protrusions 233 may be fixedly inserted into the second openings 832 of the module frame 800-1. In this case, the second protrusion 233 of the first display module LDM1 may include a first surface 233a facing the second protrusion 233 of the second display module LDM2 and a second surface 233b which is a surface opposite to the first surface 233a. In this case, a distance d41 between the first surface 233a and the module frame 800-1 may be larger than a distance d42 between the second surface 233b and the module frame 800-1.

In other words, when the module frames 800-1 and 800-2 are aligned and fitted onto the plurality of aligned display modules LDM1 and LDM2, the distance d41 between the first surface 233a and the module frame 800-1 may be larger than the distance d42 between the second surface 233b and the module frame 800-1. To enable such a structure, the formation position of the second opening 832 on the module frame 800-1 may be adjusted. According to the embodiment, the distance between the first surface 233a of the protrusion 211 and the module frame 800-1 may relatively increase, making it easier to inject the resin 980. A nozzle may be inserted into a space between the first surface 233a and the module frame 800-1 to fill the space with the resin 980.

The resin may not be injected into a gap between the second surface 233b of the second protrusion 233 and the module frame 800-1. This is because the resin may enter the display panel 100 because the second surface 233b of the second protrusion 233 is connected to the second opening 832. However, the present disclosure is not necessarily limited thereto, and an adhesive force can be strengthened by filling the entire second opening 832 with the resin.

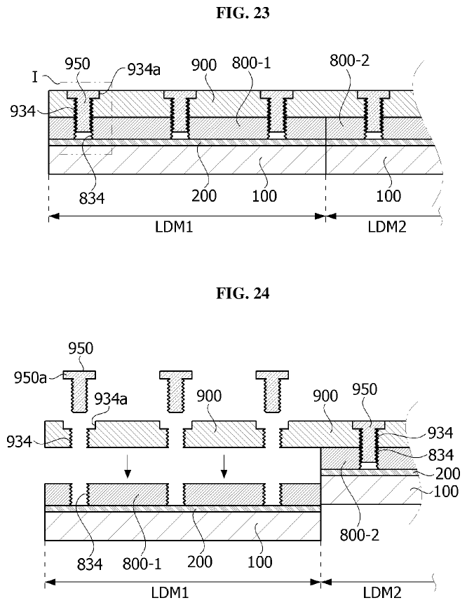

FIG. 23 is a combined cross-sectional view showing a display module frame structure in which the tiling frame and the display module are coupled by a screw according to one embodiment of the present disclosure.

Although FIG. 23 shows a structure in which the plurality of display modules LDM1 and LDM2 are coupled to a portion of the tiling display device, that is, the front surface of the tiling frame 900 as an example, the present invention is not limited thereto.

Referring to FIG. 23, each of the plurality of display modules LDM1 and LDM2 may include the display panel 100, the cover bottom 200 disposed on the rear surface of the display panel 100, and the module frames 800-1 and 800-2 coupled by being correspondingly disposed on the rear surface of the cover bottom 200.

The plurality of display module frames 800-1 and 800-2 are coupled one-to-one to the display modules LDM1 and LDM2 and is configured to support the corresponding display modules LDM1 and LDM2.

In addition, the module frames 800-1 and 800-2 are coupled by the screw 950 passing through the tiling frame 900 to be replaced.

Instead of the screw 950, other fastening members can be used, and for example, the tiling frame 900 and the module frames 800-1 and 800-2 may be fastened using a PEM bolt with a groove formed with a thread and a PEM nut coupled to the thread inside the first fastening holes 834 of the tiling frame 900 and each of the module frames 800-1 and 800-2.

In particular, each of the plurality of module frames 800-1 and 800-2 to which each of the plurality of display modules LDM1 and LDM2 is coupled is coupled to the front surface of the tiling frame 900 by the screw 950.

When the screw 950 is aligned with the second fastening hole 934 of the tiling frame 900 and the first fastening hole 834 of the module frame 800 from the rear surface of the tiling frame 900 and rotated clockwise, the module frame 800 is fastened to the tiling frame 900 by the screw 950.

When the display modules LDM1 and LDM2 are in a state of being fixed to the module frames 800-1 and 800-2, the module frames 800-1 and 800-2 and the display modules LDM1 and LDM2 may be individually fastened to the tiling frame 900. In a state in which the module frames 800-1 and 800-2 are fastened to the tiling frame 900 by the screws 950, when the module frames 800-1 and 800-2 need to be replaced, the screw 950 is rotated counterclockwise. In this case, the module frames 800-1 and 800-2 together with the display modules LDM1 and LDM2 may be separated from the tiling frame 900.

As described above, the display device module frames 800-1 and 800-2 respectively coupled to the plurality of display modules LDM1 and LDM2 are coupled to the front surface of one tiling frame 900 by the screw 950 to form the tiling display device TD according to one embodiment of the present specification.

FIG. 24 is an exploded cross-sectional view showing a state in which a module frame coupled to a rear surface of the display module to be replaced is separated from the tiling frame in the display device according to one embodiment of the present disclosure.

Referring to FIG. 24, to replace the defective display module LDM1 among the plurality of display modules LDM1 and LDM2, by unfastening the plurality of screws 950 to which the defective display module LDM1 is coupled rather than separating all of the plurality of display modules LDM1 and LDM2 from the tiling frame 900, only the defective display module LDM1 may be separated from the tiling frame 900.

In particular, when the screw 950 is separated, the screw 950 fastened to the first fastening hole 834 of the module frame 800-1 and the second fastening hole 934 of the tiling frame 900 comes out to the outside, and thus the display device module frame 800-1 is separated from the tiling frame 900.

In this case, since another display module LDM2 in contact with the defective display module LDM1 is maintained in a state of being attached to the tiling frame 900 by another screw 950, another display module LDM2 is not affected even when the defective display module LDM1 is separated.

Therefore, only the defective display module LDM1 may be easily separated from the tiling frame 900.

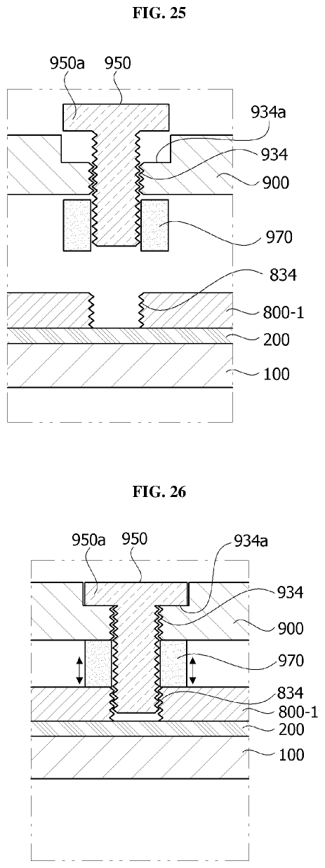

FIG. 25 is an enlarged view showing dotted line portion “I” in FIG. 23 in the display device according to one embodiment of the present disclosure, which is a cross-sectional view before a module frame to which a replaced display module is coupled and the tiling frame are coupled and a cross-sectional view showing a screw onto which a silicone ring for adjusting a step difference between the tiling frame and the module frame is fitted.

Referring to FIG. 25, the second fastening hole 934 provided in the tiling frame 900 may be fastened to the first fastening holes 834 provided in the module frames 800-1 and 800-2 to which the display modules LDM1 and LDM2 are coupled, respectively, using the screw 950 which is a fastening member.

In this case, a silicone ring 970 is fitted onto an outer surface of the screw 950 to adjust the step difference between the module frames 800-1 and 800-2 and the tiling frame 900. The silicone ring 970 may be compressed to adjust the step difference. In addition, in addition to the silicone ring 970 used to adjust the step difference, an elastic member, such as a rubber packing or leaf spring, can be used.

In addition, since a fastening seating groove 934a is formed inside an upper end of the second fastening hole 934 of the tiling frame 900 into which the screw 950 is screw-coupled by being fitted, the screw-coupling is maintained until the screw 950 is fitted into the second fastening hole 934 and a head 950a of the screw 950 is seated in the fastening seating groove 934a, and thus the screw 950 does not protrude to the outside of the tiling frame 900.

FIG. 26 is an enlarged view showing dotted line portion “I” in FIG. 23 in the display device according to one embodiment of the present disclosure, which is a combined cross-sectional view showing a coupling state of the display device in which the tiling frame and the replaced display module are coupled is coupled by the screw and a step difference between the tiling frame and the module frame is adjusted by compressing the silicon ring.

Referring to FIG. 26, the display module is re-coupled to the module frame 800-1 after the defective display module LDM1 is replaced with a new display module, and then in a state in which the module frame 800-1 is disposed on the front surface of the tiling frame 900, the tiling frame 900 and the module frame 800-1 are assembled by fitting the screw 950 into the second fastening hole 934 in the tiling frame 900 and the first fastening hole 834 in the module frame 800-1 corresponding to the second fastening hole 934, and thus the replacement with the new display module LDM1 can be easy.

In this case, the silicon ring 970 compressed by being interworked with the rotation of the screw 950 may appropriately adjust the step difference between the neighboring display modules LDM1 and LDM2 according to the amount of compression in the vertical direction. Therefore, when the module frame to which the display module is fastened is replaced, the step difference in screens of the neighboring display modules may be controlled by adjusting the amount of rotation of the screw 950.

According to the present specification, only defective display modules when defects occur in some display modules in a tiling display device including micro light emitting diodes (LEDs) can be replaced by being easily separated from a tiling frame.

In addition, according to the present specification, when a defect occurs in a single display module, by disassembling a module frame coupled to a defective display module and a screw fastened to a rear surface of a tiling frame from the tiling frame in which a plurality of display modules are coupled, it is possible to easily replace only the defective display module in the tiling frame.

Furthermore, according to the present specification, when a new display module is coupled to a tiling frame using a screw after a defective display module is replaced with a new display module, it is possible to adjust a step difference between the tiling frame and the display module using a silicon ring fitted onto the screw.

Display devices according to various embodiments of the present disclosure

may be described as follows.

A display device according to one embodiment of the present disclosure may include a plurality of display modules of which front surfaces have screens on which images are displayed, a plurality of module frames corresponding one-to-one to the display modules, and a tiling frame to which each of the plurality of module frames is fastened to be replaceable.

The display module may be correspondingly attached to the module frame.

The display device may further include a fastening member detachably fastened to the tiling frame and the module frame, wherein the module frame is coupled to or separated from the tiling frame by the fastening member.

The fastening member includes one or more first fastening holes disposed in rear surfaces of the plurality of module frames, one or more second fastening holes disposed at each position overlapping the first fastening hole in the tiling frame, and one or more screws thread-coupled to the first fastening holes and the second fastening holes.

Each of the plurality of display modules may include a display panel, a cover bottom disposed on a rear surface of the display panel, a plate bottom disposed in contact with the display panel, a circuit board, at least one flexible film for connecting the display panel to the circuit board, at least one rib disposed between the plate bottom and the circuit board, and a cover shield configured to cover the circuit board.

Each of the plurality of display modules may be correspondingly coupled to one of the module frames by being filled with a resin.

The resin may fill a space between a protrusion formed by cutting and bending one or more first openings disposed in a rear surface of each of the plurality of display modules and one or more second openings disposed at each position overlapping the first opening in the module frame so that each of the plurality of display modules is coupled to one of the plurality of module frames.

The resin may fill a space between the protrusion at one side of the first opening and the second opening through one or more third openings disposed at each position overlapping the one or more second openings in the tiling frame and is cured.

The one or more first openings may be formed in an edge portion of a cover bottom constituting the plurality of display modules.

The protrusion formed at each side of the first opening of the cover bottom may be inserted into and protrudes from the second opening of the module frame.

A silicon ring, a leaf spring, or a rubber packing may be disposed on an outer surface of the screw.

A display device according to another embodiment of the present disclosure may include a first display module, a second display module, a first module frame to which the first display module is attached, a second module frame to which the second display module is attached, and a tiling frame to which the first and second display modules are fastened to be replaceable.

The display device may further include a fastening member detachably fastened to the tiling frame and the first and second module frames, wherein the first and second module frames are coupled to or separated from the tiling frame by the fastening member.

The fastening member may include one or more first fastening holes disposed in rear surfaces of the first and second module frames, one or more second fastening holes disposed at each position overlapping the first fastening hole in the tiling frame, and one or more screws thread-coupled to the first fastening holes and the second fastening holes.

Each of the first and second display modules may be correspondingly coupled to one of the first and second module frames by being filled with a resin.

The resin may fill a space between a protrusion formed by cutting and bending one or more first openings disposed in a rear surface of each of the first and second display modules and one or more second openings disposed at each position overlapping the first opening in the first and second module frames so that each of the first and second display modules is coupled to one of the first and second module frames.

The resin may fill a space between the protrusion at one side of the first opening and the second opening through one or more third openings disposed at each position overlapping the one or more second openings in the tiling frame and is cured.

The one or more first openings may be formed in an edge portion of a cover bottom constituting the first and second display modules.

The protrusion formed at each side of the first opening of the cover bottom may be inserted into and protrudes from the second openings of the first and second module frames.

A silicon ring, a leaf spring, or a rubber packing may be disposed on an outer surface of the screw.

A display device according to another embodiment of the present disclosure may include N display modules, wherein N is a natural number of 2 or more, and a frame to which each of the display modules is fastened to be replaceable, wherein the frame includes a first frame configured to support one surface of each of the display modules so that the N display modules are disposed on the same plane, and a plurality of second frames configured to support one surface of each of M display modules, wherein M is a natural number greater than zero and less than N, each of the second frames is interposed between one of the display modules corresponding thereto and the first frame, and each of the second frames is fastened to the first frame to be replaceable.

The effects of the present disclosure are not limited to the above-described effects, and other effects that are not mentioned will be able to be clearly understood by those skilled in the art from the following description.

Since the contents of the disclosure described in the above-described technical problem, technical solution, and advantageous effects do not specify the essential features of the claims, the scope of the claims is not limited by the items described in the contents of the disclosure.

Although embodiments of the present disclosure have been described in detail with reference to the accompanying drawings, the present disclosure is not necessarily limited to these embodiments, and various modifications may be carried out without departing from the technical spirit of the present invention. Therefore, the embodiments disclosed in the present disclosure are not intended to limit the technical spirit of the present invention, but for describing it, and the scope of the technical spirit of the present invention is not limited by these embodiments. It should be understood that the above-described embodiments are illustrative and not restrictive in all respects. The scope of the present invention should be construed according to the appended claims, and all technical spirits within the equivalent range should be construed as being included in the scope of the present invention.

What is claimed is:

1. A display device comprising:
a plurality of display modules of which front surfaces have screens on which images are displayed;
a plurality of module frames corresponding one-to-one to the plurality of display modules; and
a tiling frame to which each of the plurality of module frames is fastened and is replaceable.

2. The display device of claim 1, wherein a display module from the plurality of display modules is correspondingly attached to a module frame from the plurality of module frames.

3. The display device of claim 1, further comprising:
a fastening member detachably fastened to the tiling frame and a module frame from the plurality of module frames,
wherein the module frame is coupled to or separated from the tiling frame by the fastening member.

4. The display device of claim 3, wherein the fastening member includes:
one or more first fastening holes in rear surfaces of the plurality of module frames;
one or more second fastening holes at each position overlapping the one or more first fastening holes in the tiling frame; and
one or more screws thread-coupled to the one or more first fastening holes and the one or more second fastening holes.

5. The display device of claim 1, wherein each of the plurality of display modules includes a display panel, a cover bottom on a rear surface of the display panel, a plate bottom in contact with the display panel, a circuit board, at least one flexible film connecting the display panel to the circuit board, at least one rib between the plate bottom and the circuit board, and a cover shield that covers the circuit board.

6. The display device of claim 1, wherein each of the plurality of display modules is correspondingly coupled to one of the plurality of module frames with a resin.

7. The display device of claim 6, wherein the resin fills a space between a protrusion from a cut and bent one or more first openings in a rear surface of each of the plurality of display modules and one or more second openings disposed at each position overlapping the one or more first openings in the module frame such that each of the plurality of display modules is coupled to one of the plurality of module frames.

8. The display device of claim 7, wherein the resin fills a space between the protrusion at one side of the one or more first openings and the one or more second openings through one or more third openings disposed at each position overlapping the one or more second openings in the tiling frame and is cured.

9. The display device of claim 7, wherein the one or more first openings are in an edge portion of a cover bottom forming the plurality of display modules

10. The display device of claim 9, wherein the protrusion at each side of the one or more first openings of the cover bottom is inserted into and protrudes from the one or more second openings of the module frame.

11. The display device of claim 4, wherein a silicon ring, a leaf spring, or a rubber packing is on an outer surface of the one or more screws.

12. A display device comprising:
a first display module;
a second display module;
a first module frame attached to the first display module;
a second module frame attached to the second display module; and
a tiling frame that is fastened to the first display module and the second display module and is replaceable.

13. The display device of claim 12, further comprising:
a fastening member detachably fastened to the tiling frame and the first module frame and the second module frame,
wherein the first module frame and the second module frame are coupled to or separated from the tiling frame by the fastening member.

14. The display device of claim 13, wherein the fastening member includes:
one or more first fastening holes in rear surfaces of the first module frame and the second module frame;
one or more second fastening holes at each position overlapping the one or more first fastening holes in the tiling frame; and
one or more screws thread-coupled to the one or more first fastening holes and the one or more second fastening holes.

15. The display device of claim 12, wherein each of the first display module and the second display module is correspondingly coupled to one of the first module frame and the second module frame with a resin.

16. The display device of claim 15, wherein the resin fills a space between a protrusion included in a cut and bent one or more first openings disposed in a rear surface of each of the first display module and the second display module and one or more second openings disposed at each position overlapping the one or more first openings in the first module frame and the second module frame such that each of the first display module and the second display module is coupled to one of the first module frame and the second module frame.

17. The display device of claim 16, wherein the resin fills a space between the protrusion at one side of the one or more first openings and the one or more second openings through one or more third openings disposed at each position overlapping the one or more second openings in the tiling frame and is cured.

18. The display device of claim 16, wherein the one or more first openings are in an edge portion of a cover bottom forming the first display module and the second display module.

19. The display device of claim 18, wherein the protrusion at each side of the one or more first openings of the cover bottom is inserted into and protrudes from the one or more second openings of the first module frame and the second module frame.

20. The display device of claim 14, wherein a silicon ring, a leaf spring, or a rubber packing is on an outer surface of the one or more screws.

21. A display device comprising:
N display modules, wherein N is a natural number of 2 or more; and
a frame to which each of the N display modules is fastened and is replaceable,
wherein the frame includes:
a first frame configured to support one surface of each of the N display modules so that the N display modules are on a same plane; and
a plurality of second frames configured to support one surface of each of M display modules, wherein M is a natural number greater than zero and less than N,
each of the plurality of second frames is interposed between one of the M display modules corresponding thereto and the first frame, and
each of the plurality of second frames is fastened to the first frame and is replaceable.
